(19) United States
(12) Patent Application Publication
(10) Pub. No.: US 2018/0208820 A1
(43) Pub. Date: Jul. 26, 2018

(54) THERMAL CONDUCTIVE RESIN COMPOSITION, THERMAL CONDUCTIVE SHEET, AND SEMICONDUCTOR DEVICE

(71) Applicant: SUMITOMO BAKELITE CO., LTD., Tokyo (JP)

(72) Inventors: Mika Tsuda, Tokyo (JP); Haruyuki Hatano, Tokyo (JP); Kazuya Kitagawa, Tokyo (JP); Keita Nagahashi, Tokyo (JP)

(73) Assignee: SUMITOMO BAKELITE CO., LTD., Tokyo (JP)

(21) Appl. No.: 15/746,089

(22) PCT Filed: Jul. 20, 2016
(86) PCT No.: PCT/JP2016/071287

§ 371 Date: Jan. 19, 2018

(30) Foreign Application Priority Data
Jul. 21, 2015 (JP) 2015-144170

(51) Int. Cl. C09K 5/14; C08L 79/04; C08J 5/18; H01L 23/373; H01L 23/495

(52) U.S. Cl. CPC C09K 5/14; H01L 24/48; C08J 5/18; H01L 23/3733; H01L 23/49568; H01L 23/49586; C08L 2203/20; C08L 2205/025; C08L 2205/035; C08J 2379/04; C08J 2463/08; C08J 2463/00; C08J 2463/02; H01L 23/49575; C08L 79/04

(57) ABSTRACT

The thermal conductive resin composition of first embodiment includes an epoxy resin, a cyanate resin, and thermal conductive filler. It has a thermal conductivity at 25° C., and cracking does not occur when a specific flex resistance test is carried out. The thermal conductive resin composition of a second embodiment includes an epoxy resin, a thermal conductive filler, and silica nanoparticles. An average particle diameter D₅₀ of the silica nanoparticles is equal to or more than 1 nm and equal to or less than 100 nm, a content of the silica nanoparticles is equal to or more than 0.3% by mass and equal to or less than 2.5% by mass with respect to 100% by mass of a total solid content of the thermal conductive resin composition. The thermal conductive filler includes secondary agglomerated particles constituted of primary particles of scale-like boron nitride.

### TECHNICAL FIELD

The present invention relates to a thermal conductive resin composition, a thermal conductive sheet, and a semiconductor device.

### BACKGROUND ART

Hitherto, inverter devices or power semiconductor devices constituted by mounting semiconductor chips such as insulated gate bipolar transistors (IGBTs) and diodes, resistors, and electronic components such as capacitors on a substrate have been known.

These power control devices are applied to a variety of instruments depending on the voltage resistance or current capacity thereof. Particularly, from the viewpoint of the recent environmental issues and energy-saving initiative, the use of these power control devices in a variety of electric machines has been expanding every year.

Particularly, for in-vehicle power control devices, there is a demand for the installation of power control devices in engine rooms together with size reduction and space saving. In engine rooms, the temperature is high and severe environments such as significantly changing temperatures are formed, and thus members having more favorable heat dissipation properties and insulation properties at high temperatures are required.

For example, Patent Document 1 (Japanese Unexamined Patent Publication No. 2011-216619) discloses a semiconductor device in which a semiconductor chip is mounted on a support such as a lead frame, and the support and a metal plate that is connected to a heat sink are adhered to each other through an insulating resin adhesive layer.

In addition, Patent Document 2 (pamphlet of International Publication No. 2012/070289) discloses a thermal conductive sheet including secondary particles constituted of the primary particles of boron nitride.

### RELATED DOCUMENT

### Patent Document

[Patent Document 1] Japanese Unexamined Patent Publication No. 2011-216619

[Patent Document 2] Pamphlet of International Publication No. 2012/070289

### SUMMARY OF THE INVENTION

### Technical Problem

However, the semiconductor device described in Patent Document 1 was not capable of sufficiently satisfying heat dissipation properties and insulation properties at high temperatures. Therefore, there are cases in which it is difficult to sufficiently dissipate heat from the semiconductor chip to the outside or maintain the insulation properties of the semiconductor device, and, in such cases, the performance of the semiconductor device degrades.

In addition, the thermal conductive sheet described in Patent Document 2 is, generally, obtained by preparing a varnish-form resin composition, applying and drying this composition on a base material so as to produce a thermal conductive sheet in a B-stage state, and furthermore, heating and curing this thermal conductive sheet.

However, according to the present inventors' studies, it has been clarified that, in thermal conductive sheets in a B-stage state as described in Patent Document 2, when an inorganic filler is tightly packed, the thermal conductive sheets easily crack and powder is likely to drop, and thus the handling properties deteriorate. Therefore, it has been clarified that, in the above-described thermal conductive sheets, it is difficult to stably manufacture semiconductor devices.

A first invention of the present invention has been made in consideration of the above-described circumstances and provides a thermal conductive resin composition that can be used to stably manufacture semiconductor devices having excellent reliability.

In addition, in resin varnish of the related art as described in Patent Document 2, thermal conductive fillers easily settle, and thus there has been room for the improvement of preservation stability.

A second invention of the present invention has been made in consideration of the above-described circumstances and provides a thermal conductive resin composition having excellent preservation stability.

### Solution to Problem

According to the first invention of the present invention, there is provided a thermal conductive resin composition including an epoxy resin, a cyanate resin, and a thermal conductive filler, in which a thermal conductivity at 25° C., which is measured by the following thermal conductivity test, is equal to or more than 3 W/(m·K), and cracking does not occur when the following flex resistance test is carried out.

<Thermal Conductivity Test>

The thermal conductive resin composition is thermally treated at 100° C. for 30 minutes, thereby producing a B-stage-form thermal conductive sheet having a film thickness of 400 μm. Next, the thermal conductive sheet is thermally treated at 180° C. and 10 MPa for 40 minutes, thereby obtaining a thermal conductive sheet cured substance. Next, the thermal conductivity of the thermal conductive sheet cured substance in a thickness direction is measured using a laser flash method.

<Flex Resistance Test>

The thermal conductive resin composition is thermally treated at 100° C. for 30 minutes, thereby producing a B-stage-form thermal conductive sheet having a film thickness of 400 μm. Next, a 100 mm×10 mm piece is cut out from the thermal conductive sheet and is folded along a curved surface of a cylinder having a diameter of 10 mm at a bending angle of 180 degrees in an environment of 25° C. at a central portion in a longitudinal direction.

Furthermore, according to the second invention of the present invention,

there is provided a thermal conductive resin composition including an epoxy resin, a thermal conductive filler, and silica nanoparticles, in which an average particle diameter D₅₀ of the silica nanoparticles, which is measured using a dynamic light scattering method, is equal to or more than 1 nm and equal to or less than 100 nm, a content of the silica nanoparticles is equal to or more than 0.3% by mass and equal to or less than 2.5% by mass with respect to 100% by mass of the total solid content of the thermal conductive resin composition, and

the thermal conductive filler includes secondary agglomerated particles constituted of primary particles of scale-like boron nitride.

Furthermore, according to the present invention,

there is provided a thermal conductive sheet formed by semi-curing the thermal conductive resin composition of the first invention or the second invention.

Furthermore, according to the present invention,

there is provided a semiconductor device including a metal plate, a semiconductor chip provided on a first surface side of the metal plate, a thermal conductive material joined to a second surface of the metal plate on a side opposite to the first surface, and an encapsulating resin that encapsulates the semiconductor chip and the metal plate, in which the thermal conductive material is formed of the thermal conductive sheet of the first invention or the second invention.

### Advantageous Effects of Invention

According to the first invention of the present invention, it is possible to provide a thermal conductive resin composition that can be used to stably manufacture semiconductor devices having excellent reliability, a thermal conductive sheet, and a semiconductor device having excellent reliability.

In addition, according to the second invention of the present invention, it is possible to provide a thermal conductive resin composition having excellent preservation stability, and a thermal conductive sheet and a semiconductor device for which the thermal conductive resin composition is used.

### BRIEF DESCRIPTION OF THE DRAWINGS

The above-described object, other objects, characteristics, and advantages will be further clarified using preferred embodiments described below and the following drawings associated thereto.

FIG. 1 is a cross-sectional view of a semiconductor device according to an embodiment of a first invention and a second invention.

FIG. 2 is a cross-sectional view of the semiconductor device according to another embodiment of the first invention and the second invention.

### DESCRIPTION OF EMBODIMENTS

Hereinafter, embodiments of the present invention will be described on the basis of the drawings. Meanwhile, in all of the drawings, the same constituent element will be given the same reference sign, and the detailed description thereof will not be repeated so as to avoid duplication. In addition, the drawings are schematic views, and dimensional ratios do not coincide with actual ratios. In addition, “to” used to express numerical ranges indicates “equal to or more than and equal to or less than” unless particularly otherwise described.

[First Invention]

Hereinafter, an embodiment according to a first invention will be described.

First, a thermal conductive resin composition (P) according to the present embodiment will be described.

The thermal conductive resin composition (P) according to the present embodiment includes an epoxy resin (A1), a cyanate resin (A2), and a thermal conductive filler (B).

In addition, the thermal conductive resin composition (P) according to the present embodiment has a thermal conductivity at 25° C., which is measured by the following thermal conductivity test, of equal to or more than 3 W/(m·K) and preferably equal to or more than 10 W/(m·K) and does not crack when the following flex resistance test is carried out. Here, “crack” refers to cleavage that is generated on thermal conductive sheet surfaces, the long side of the cleavage is equal to or more than 2 mm, and the maximum value of the cleavage width in a direction perpendicular to the long side is equal to or more than 50 μm. Meanwhile, there are cases in which cleavage is intermittent in the long side direction, and, when the distance between separated cleavage parts is less than 1 mm, the cleavage is determined as one continuous cleavage.

<Thermal Conductivity Test>

The thermal conductive resin composition (P) is thermally treated at 100° C. for 30 minutes, thereby producing a B-stage-form thermal conductive sheet having a film thickness of 400 μm. Next, the thermal conductive sheet is thermally treated at 180° C. and 10 MPa for 40 minutes, thereby obtaining a thermal conductive sheet cured substance. Next, the thermal conductivity of the thermal conductive sheet cured substance in the thickness direction is measured using a laser flash method.

<Flex Resistance Test>

The thermal conductive resin composition is thermally treated at 100° C. for 30 minutes, thereby producing a B-stage-form thermal conductive sheet having a film thickness of 400 μm. Next, a 100 mm×10 mm piece is cut out from the thermal conductive sheet and is folded along the curved surface of a cylinder having a diameter of 10 mm at a bending angle of 180 degrees in an environment of 25° C. at the central portion in the longitudinal direction.

According to the thermal conductive resin composition (P) according to the present embodiment, due to the above-described constitution, it is possible to stably manufacture semiconductor devices having excellent reliability.

Meanwhile, in the present embodiment, the thermal conductive resin composition (P) in a B-stage state which has a sheet shape and is formed by semi-curing the thermal conductive resin composition (P) will be referred to as “thermal conductive sheet”. In addition, a substance obtained by curing the thermal conductive sheet will be referred to as “thermal conductive sheet cured substance”. In addition, the thermal conductive sheet which is applied to semiconductor devices and is cured will be referred to as “thermal conductive material”.

The thermal conductive resin composition (P) according to the present embodiment includes an epoxy resin (A1), a cyanate resin (A2), and a thermal conductive filler (B). Therefore, it is possible to improve the balance between the heat dissipation properties and the insulation properties of thermal conductive sheet cured substances to be obtained.

The thermal conductive material is provided in, for example, a joint interface in which high thermal conduction properties in semiconductor devices are required and accelerates thermal conduction from heat generation bodies to heat dissipation bodies. Therefore, faults attributed to characteristic alteration in semiconductor chips and the like are suppressed, and the stability of semiconductor devices can be improved.

An example of semiconductor devices to which the thermal conductive sheet according to the present embodiment is applied is a structure in which, for example, a semiconductor chip is provided on a heat sink (metal plate), and the thermal conductive material is provided on the surface of the heat sink on a side opposite to the surface to which the semiconductor chip is joined.

In addition, another example of semiconductor devices to which the thermal conductive sheet according to the present embodiment is applied is a semiconductor device including the thermal conductive material, a semiconductor chip joined to one surface of the thermal conductive material, a metal member joined to the surface of the thermal conductive material on a side opposite to the above-described surface, and an encapsulating resin that encapsulates the thermal conductive material, the semiconductor chip, and the metal member.

According to the present inventors' studies, it was found that, when a combination of an epoxy resin, a cyanate resin, and a thermal conductive filler is added to the thermal conductive resin composition, the insulation properties at high temperatures of cured substances of the thermal conductive resin composition further improve. The reason therefor is considered that the cyanate resin being included improves the curing density of the cured substances, and the motion opening of conductive components in the cured substances at high temperatures is suppressed. When the motion opening of conductive components is suppressed, it is possible to suppress the insulation properties of the cured substances being degraded by an increase in temperature.

Meanwhile, according to the present inventors' studies, it has been clarified that, when the thermal conductive resin composition only includes an epoxy resin, a cyanate resin, and a thermal conductive filler, it is difficult to stably manufacture semiconductor devices having excellent reliability such as insulation reliability.

Therefore, as a result of more intensive studies in consideration of the above-described circumstances, the present inventors found that, when a combination of the epoxy resin (A1), the cyanate resin (A2), and the thermal conductive filler (B) is added to the thermal conductive resin composition (P), the thermal conductivity at 25° C., which is measured by the thermal conductivity test, is set to be equal to or more than the above-described lower limit value, and furthermore, characteristics that prevent the thermal conductive resin composition from cracking when the flex resistance testis carried out are imparted, it is possible to stably manufacture semiconductor devices having excellent reliability such as insulation reliability.

The thermal conductivity or the characteristics that prevent the thermal conductive resin composition from cracking when the flex resistance test is carried out in the thermal conductive resin composition (P) according to the present embodiment can be controlled by appropriately adjusting the kinds or blending ratios of the respective components constituting the thermal conductive resin composition (P) and the method for preparing the thermal conductive resin composition (P).

In the present embodiment, examples of factors for controlling the thermal conductivity or the characteristics that prevent the thermal conductive resin composition from cracking when the flex resistance test is carried out include the appropriate selection of the kind of, particularly, the epoxy resin (A1) or the thermal conductive filler (B), the additional inclusion of a flexibility-imparting agent (D) described below, the aging of a resin varnish to which the epoxy resin (A1) and the thermal conductive filler (B) are added, heating conditions in the aging, and the like.

In the thermal conductive resin composition (P) according to the present embodiment, the glass transition temperature of cured substances of the thermal conductive resin composition (P), which is measured by a dynamic mechanical analysis under conditions of a temperature-increase rate of 5° C./min and a frequency of 1 Hz, is preferably equal to or higher than 175° C. and more preferably equal to or higher than 190° C. The upper limit value of the glass transition temperature is not particularly limited and is, for example, equal to or lower than 300° C.

Here, the glass transition temperature of cured substances of the thermal conductive resin composition (P) can be measured, for example, as described below. First, the thermal conductive resin composition (P) is thermally treated at 100° C. for 30 minutes, thereby producing a B-stage-form thermal conductive sheet having a film thickness of 400 μm. Next, the thermal conductive sheet is thermally treated at 180° C. and 10 MPa for 40 minutes, thereby obtaining a thermal conductive sheet cured substance. Next, the glass transition temperature (Tg) of the obtained cured substance is measured by the dynamic mechanical analysis (DMA) under conditions of a temperature-increase rate of 5° C./min and a frequency of 1 Hz.

When the glass transition temperature is equal to or higher than the lower limit value, it is possible to further suppress the motion opening of conductive components, and thus it is possible to further suppress the insulation properties of the cured substance being degraded by an increase in temperature. As a result, it is possible to realize semiconductor devices having more favorable insulation reliability.

The glass transition temperature can be controlled by appropriately adjusting the kinds or blending ratios of the respective components constituting the thermal conductive resin composition (P) and the method for preparing the thermal conductive resin composition (P).

In the thermal conductive resin composition (P) according to the present embodiment, the volume resistivity at 175° C. of the cured substance of the thermal conductive resin composition (P), which is on the basis of JIS K6911 and is measured one minute after the application of a voltage at an applied voltage of 1,000 V, is preferably equal to or more than 1.0×10⁹ Ω·m and more preferably equal to or more than 1.0×10¹⁰ Ω·m. The upper limit value of the volume resistivity at 175° C. is not particularly limited and is, for example, equal to or less than 1.0×10¹³ Ω·m.

Here, the volume resistivity at 175° C. of the cured substance of the thermal conductive resin composition (P) can be measured, for example, as described below. First, the thermal conductive resin composition (P) is thermally treated at 100° C. for 30 minutes, thereby producing a B-stage-form thermal conductive sheet having a film thickness of 400 μm. Next, the thermal conductive sheet is thermally treated at 180° C. and 10 MPa for 40 minutes, thereby obtaining a thermal conductive sheet cured substance. Next, the volume resistivity of the obtained cured substance is measured one minute after the application of a voltage at an applied voltage of 1,000 V on the basis of JIS K6911.

Here, the volume resistivity at 175° C. represents an index of the insulation properties at high temperatures of the thermal conductive sheet cured substance. That is, as the volume resistivity at 175° C. increases, the insulation properties at high temperatures become more favorable.

The volume resistivity at 175° C. of the cured substance of the thermal conductive resin composition (P) according to the present embodiment can be controlled by appropriately adjusting the kinds or blending ratios of the respective components constituting the thermal conductive resin composition (P) and the method for preparing the thermal conductive resin composition (P).

In the thermal conductive resin composition (P) according to the present embodiment, the storage elastic modulus E′ at 50° C. of the cured substance of the thermal conductive resin composition (P) is preferably equal to or more than 10 GPa and equal to or less than 40 GPa and more preferably equal to or more than 15 GPa and equal to or less than 35 GPa.

When the storage elastic modulus E′ is in the above-described range, the stiffness of cured substances to be obtained becomes appropriate, and, even in a case in which ambient temperature changes, it is possible to stably relax stress which is generated between members due to the difference in linear expansion coefficient in the cured substances. Therefore, it is possible to further enhance the joint reliability between individual members.

Here, the storage elastic modulus E′ at 50° C. can be measured, for example, as described below. First, the thermal conductive resin composition (P) is thermally treated at 100° C. for 30 minutes, thereby producing a B-stage-form thermal conductive sheet having a film thickness of 400 μm. Next, the thermal conductive sheet is thermally treated at 180° C. and 10 MPa for 40 minutes, thereby obtaining a thermal conductive sheet cured substance. Next, the storage elastic modulus E′ at 50° C. of the obtained cured substance is measured by a dynamic mechanical analysis (DMA). Here, the storage elastic modulus E′ is the value of the storage elastic modulus E′ at 50° C. which is measured from 25° C. to 300° C. at a frequency of 1 Hz and a temperature-increase rate of 5 to 10° C./minute after a tensile load is applied to the thermal conductive sheet cured substance.

The storage elastic modulus E′ at 50° C. of the cured substance of the thermal conductive resin composition (P) according to the present embodiment can be controlled by appropriately adjusting the kinds or blending ratios of the respective components constituting the thermal conductive resin composition (P) and the method for preparing the thermal conductive resin composition (P).

Thermal conductive materials formed of the thermal conductive resin composition (P) according to the present embodiment are provided, for example, between heat generation bodies such as semiconductor chips and substrates on which the heat generation bodies are mounted such as lead frames or wiring substrates (interposers) or between the substrates and heat dissipation members such as heat sinks. Therefore, it is possible to maintain the insulation properties of semiconductor devices and effectively dissipate heat generated from the heat generation bodies to the outside of semiconductor devices. Therefore, it becomes possible to improve the reliability of semiconductor devices.

Hereinafter, the respective components constituting the thermal conductive resin composition (P) will be described.

The thermal conductive resin composition (P) according to the present embodiment includes the epoxy resin (A1), the cyanate resin (A2), and the thermal conductive filler (B).

(Epoxy Resin (A1))

Examples of the epoxy resin (A1) include bisphenol-type epoxy resins such as bisphenol A-type epoxy resins, bisphenol F-type epoxy resins, bisphenol E-type epoxy resins, bisphenol S-type epoxy resins, bisphenol M-type epoxy resins (4,4′-(1,3-phenylenediisopridien) bisphenol-type epoxy resin), bisphenol P-type epoxy resins (4,4′-(1,4-phenylenediisopridien) bisphenol-type epoxy resin), and bisphenol Z-type epoxy resins (4,4′-cyclohexadiene bisphenol-type epoxy resin); novolac-type epoxy resins such as phenol novolac-type epoxy resins, cresol novolac-type epoxy resins, tetraphenol group ethane-type novolac-type epoxy resins, and novolac-type epoxy resins having a condensed ring aromatic hydrocarbon structure; epoxy resins having a biphenyl skeleton; arylalkylene-type epoxy resins such as xylylene-type epoxy resins and epoxy resins having a biphenyl aralkyl skeleton; naphthalene-type epoxy resins such as naphthylene ether-type epoxy resins, naphthol-type epoxy resins, naphthalene diol-type epoxy resins, bifunctional or tetrafunctional epoxy-type naphthalene resins, binaphthyl-type epoxy resins, and epoxy resins having a naphthalene aralkyl skeleton; anthracene-type epoxy resins; phenoxy-type epoxy resins; epoxy resins having a dicyclopentadiene skeleton; norbornene-type epoxy resins; epoxy resins having an adamantane skeleton; fluorine-type epoxy resins; epoxy resin having a phenol aralkyl skeleton; and the like.

Meanwhile, in the present embodiment, epoxy resins in a liquid form at 25° C. which will be described below are not included in the scope of the epoxy resin (A1).

Among these, the epoxy resin (A1) is preferably an epoxy resin having a dicyclopentadiene skeleton, an epoxy resin having an adamantane skeleton, an epoxy resin having a phenol aralkyl skeleton, an epoxy resin having a biphenyl aralkyl skeleton, an epoxy resin having a naphthalene aralkyl skeleton, or the like.

As the epoxy resin (A1), one of these resins may be used singly or two or more resins may be jointly used.

When the above-described epoxy resin (A1) is used, the glass transition temperature of the thermal conductive sheet cured substance increases, and it is possible to improve the heat dissipation properties and the insulation properties of the thermal conductive sheet cured substance.

The content of the epoxy resin (A1) in the thermal conductive resin composition (P) according to the present embodiment is preferably equal to or more than 0.5% by mass and equal to or less than 15% by mass and more preferably equal to or more than 1% by mass and equal to or less than 12% by mass with respect to 100% by mass of the total solid content of the thermal conductive resin composition (P). When the content of the epoxy resin (A1) is equal to or more than the lower limit value, the content of the cyanate resin (A2) relatively decreases, and there are cases in which the moisture resistance improves. When the content of the epoxy resin (A1) is equal to or less than the upper limit value, the handling properties improve, and it becomes easy to form the thermal conductive sheet cured substance.

Meanwhile, in the present embodiment, the total solid content of the thermal conductive resin composition (P) refers to components remaining in a solid content form when the thermal conductive resin composition (P) is heated and cured, and, for example, components that are volatilized by heating such as solvents are not included in the scope of the total solid content. Meanwhile, epoxy resins in a liquid format 25° C. and liquid-form components such as coupling agents are incorporated into the solid content of the thermal conductive resin composition (P) when heated and cured and are thus included in the scope of the total solid content.

(Cyanate Resin (A2))

Examples of the cyanate resin (A2) include novolac-type cyanate resins; bisphenol-type cyanate resins such as bisphenol A-type cyanate resins, bisphenol E-type cyanate resins, and tetramethyl bisphenol F-type cyanate resins; naphthol aralkyl-type cyanate resins obtained by reactions between naphthol aralkyl-type phenol resins and cyanogen halides; dicyclopentadiene-type cyanate resins; biphenyl alkyl-type cyanate resins, and the like. Among these, novolac-type cyanate resins and naphthol aralkyl-type cyanate resins are preferred, and novolac-type cyanate resins are more preferred. When novolac-type cyanate resins are used, the crosslinking density of thermal conductive sheet cured substances to be obtained further increases, and it is possible to further improve the heat resistance of cured substances.

As the novolac-type cyanate resins, for example, novolac-type cyanate resins represented by General Formula (I) can be used.

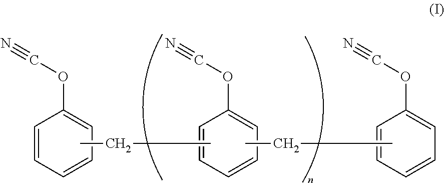

The average repeating unit n of the novolac-type cyanate resins represented by General Formula (I) is an arbitrary integer. The average repeating unit n is not particularly limited, but is preferably equal to or more than one and more preferably equal to or more than two. When the average repeating unit n is equal to or more than the lower limit value, the heat resistance of the novolac-type cyanate resins improves, and it is possible to further suppress low-weight bodies being desorbed and volatilized during heating. In addition, the average repeating unit n is not particularly limited, but is preferably equal to or less than 10 and more preferably equal to or less than seven. When n is equal to or less than the upper limit value, it is possible to suppress the melt viscosity becoming high and improve the formability of the thermal conductive sheet cured substance.

In addition, as the cyanate resin, naphthol aralkyl-type cyanate resins represented by General Formula (II) can also preferably used. The naphthol aralkyl-type cyanate resins represented by General Formula (II) are obtained by, for example, condensing naphthol aralkyl-type phenol resins that are obtained by reactions between naphthols such as α-naphthol or β-naphthol and p-xylylene glycol, α,α′-dimethoxy-p-xylene, 1,4-di(2-hydroxy-2-propyl)benzene, or the like and cyanogen halides. The repeating unit n of General Formula (II) is preferably an integer of equal to or less than 10. When the repeating unit n is equal to or less than 10, it is possible to obtain more uniform thermal conductive sheets. In addition, there is a tendency that, during syntheses, polymerization does not easily occur in molecules, liquid separation properties during water washing improve, and yield decreases can be prevented.

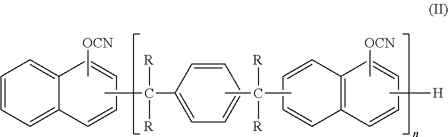

(In the formula, R's each independently represent a hydrogen atom or a methyl group, and n represents an integer of equal to or more than 1 and equal to or less than 10.)

In addition, as the cyanate resin, one cyanate resin may be used singly, two or more cyanate resins may be jointly used, and one or more cyanate resins and prepolymers thereof may be jointly used.

The content of the cyanate resin (A2) in the thermal conductive resin composition (P) according to the present embodiment is preferably equal to or more than 2% by mass and equal to or less than 25% by mass and more preferably equal to or more than 5% by mass and equal to or less than 20% by mass with respect to 100% by mass of the total solid content of the thermal conductive resin composition (P). When the content of the cyanate resin (A2) is equal to or more than the lower limit value, the insulation properties of thermal conductive sheet cured substances to be obtained further improve, and it is possible to improve the flexibility and the flex resistance of thermal conductive sheets to be obtained, and thus it is possible to suppress the handling properties of thermal conductive sheets being degraded by the tight packing of the thermal conductive filler (B). When the content of the cyanate resin (A2) is equal to or less than the upper limit value, there are cases in which the moisture resistance of thermal conductive sheet cured substances to be obtained improves.

In addition, the total content of the epoxy resin (A1) and the cyanate resin (A2) in the thermal conductive resin composition (P) according to the present embodiment is preferably equal to or more than 5% by mass and equal to or less than 40% by mass and more preferably equal to or more than 9% by mass and equal to or less than 30% by mass with respect to 100% by mass of the total solid content of the thermal conductive resin composition (P). When the total content of the epoxy resin (A1) and the cyanate resin (A2) is equal to or more than the lower limit value, the handling properties of the thermal conductive sheet improve, and it becomes easy to form thermal conductive sheet cured substances. When the total content of the epoxy resin (A1) and the cyanate resin (A2) is equal to or less than the upper limit value, the strength or the flame resistance of thermal conductive sheet cured substances further improves or the thermal conduction properties of thermal conductive sheet cured substances further improves.

(Thermal Conductive Filler (B))

Examples of the thermal conductive filler (B) include alumina, boron nitride, aluminum nitride, silicon nitride, silicon carbide, and the like. As the thermal conductive filler, one filler may be used singly or two or more fillers may be jointly used.

From the viewpoint of further improving the thermal conduction properties of the thermal conductive sheet cured substance according to the present embodiment, the thermal conductive filler (B) is preferably secondary agglomerated particles that are formed by agglomerating the primary particles of scale-like boron nitride.

The secondary agglomerated particles that are formed by agglomerating the scale-like boron nitride can be formed by, for example, agglomerating scale-like boron nitride using a spray drying method or the like and then firing the boron nitride. The firing temperature is, for example, 1,200° C. to 2,500° C.

In a case in which the secondary agglomerated particles that are obtained by firing scale-like boron nitride are used as described above, from the viewpoint of improving the dispersibility of the thermal conductive filler (B) in the epoxy resin (A1), the epoxy resin (A1) is particularly preferably an epoxy resin having a dicyclopentadiene skeleton.

The average particle diameter of the secondary agglomerated particles that are formed by agglomerating scale-like boron nitride is, for example, preferably equal to or more than 5 μm and equal to or less than 180 μm and more preferably equal to or more than 10 μm and equal to or less than 100 μm. In such a case, it is possible to realize thermal conductive sheet cured substances being more favorable in terms of the balance between the thermal conduction properties and the insulation properties.

The average long diameter of the primary particles of scale-like boron nitride which constitute the secondary agglomerated particles is preferably equal to or more than 0.01 μm and equal to or less than 40 μm and more preferably equal to or more than 0.1 μm and equal to or less than 20 μm. In such a case, it is possible to realize thermal conductive sheet cured substances being more favorable in terms of the balance between the thermal conduction properties and the insulation properties.

Meanwhile, this average long diameter can be measured using an electron microscope photograph. For example, the average long diameter is measured in the following order. First, samples are produced by cutting the secondary agglomerated particles using a microtome or the like. Next, several cross-sectional photographs of the secondary agglomerated particles magnified to several thousand times are captured using a scanning electron microscope. Next, arbitrary secondary agglomerated particles are selected, and the long diameters of the primary particles of the scale-like boron nitride are measured from the photographs. At this time, the long diameters of ten or more primary particles are measured, and the average value thereof is considered as the average long diameter.

The content of the thermal conductive filler (B) in the thermal conductive resin composition (P) according to the present embodiment is preferably equal to or more than 50% by mass and equal to or less than 92% by mass, more preferably equal to or more than 55% by mass and equal to or less than 88% by mass, and particularly preferably equal to or more than 60% by mass and equal to or less than 85% by mass with respect to 100% by mass of the total solid content of the thermal conductive resin composition (P).

When the content of the thermal conductive filler (B) is equal to or more than the lower limit value, it is possible to more effectively improve the thermal conduction properties or the mechanical strength of thermal conductive sheet cured substances to be obtained. Meanwhile, when the content of the thermal conductive filler (B) is equal to or less than the upper limit value, the film formation properties or the workability of the thermal conductive resin composition (P) are improved, and it is possible to further improve the uniformity of the film thickness of thermal conductive sheets to be obtained.

From the viewpoint of further improving the thermal conduction properties of thermal conductive sheet cured substances, the thermal conductive filler (B) according to the present embodiment preferably further includes, in addition to the secondary agglomerated particles, the primary particles of scale-like boron nitride which are different from the primary particles of scale-like boron nitride which constitute the secondary agglomerated particles. The average long diameter of the primary particles of scale-like boron nitride is preferably equal to or more than 0.01 μm and equal to or less than 40 μm and more preferably equal to or more than 0.1 μm and equal to or less than 30 μm.

In such a case, it is possible to realize thermal conductive sheet cured substances being more favorable in terms of the balance between the thermal conduction properties and the insulation properties.

From the viewpoint of suppressing the settlement of the thermal conductive filler (B) in varnish-form thermal conductive resin compositions (P) and improving the preservation stability of the thermal conductive resin composition (P), the thermal conductive resin composition (P) according to the present embodiment preferably further includes silica nanoparticles (C).

The average particle diameter D₅₀ of the silica nanoparticles (C) which is measured using a dynamic light scattering method is preferably equal to or more than 1 nm and equal to or less than 100 nm, more preferably equal to or more than 10 nm and equal to or less than 100 nm, and particularly preferably equal to or more than 10 nm and equal to or less than 70 nm. When the average particle diameter D₅₀ of the silica nanoparticles (C) is in the above-described range, it is possible to further suppress the settlement of the thermal conductive filler (B) in varnish-form thermal conductive resin compositions (P).

Meanwhile, the average particle diameter of the silica nanoparticles (C) can be measured using, for example, a dynamic light scattering method. The particles are dispersed in water using ultrasonic waves, the volume-based particle size distribution of the particles is measured using a dynamic light scattering method-type particle size distribution measurement instrument (manufactured by Horiba, Ltd., LB-550), and the median diameter (D₅₀) is considered as the average particle diameter.

In addition, the content of the silica nanoparticles (C) is preferably equal to or more than 0.3% by mass and equal to or less than 2.5% by mass, more preferably equal to or more than 0.4% by mass and equal to or less than 2.0% by mass, and particularly preferably equal to or more than 0.5% by mass and equal to or less than 1.8% by mass with respect to 100% by mass of the total solid content of the thermal conductive resin composition (P).

When the content of the silica nanoparticles (C) is in the above-described range, the settlement of the thermal conductive filler (B) in varnish-form thermal conductive resin compositions (P) is further suppressed, and it is possible to further improve the handling properties and the preservation stability of the thermal conductive resin composition (P).

The method for manufacturing the silica nanoparticles (C) is not particularly limited, examples thereof include combustion methods such as a vaporized metal combustion (VMC) method and a physical vapor synthesis (PVS) method, melting methods in which crushed silica is flame-melted, settlement methods, gel methods, and the like, and, among these, the VMC method is particularly preferred.

The VMC method refers to a method in which silicon powder is injected into chemical flame formed in oxygen-containing gas, combusted, and then cooled, thereby forming silica particles. In the VMC method, the particle diameters of silica particles to be obtained can be adjusted by adjusting the particle diameters and injection amount of silicon powder to be injected, the flame temperature, and the like, and thus it is possible to manufacture silica particles having different particle diameters.

As the silica nanoparticles (C), commercially available products such as RX-200 (manufactured by Nippon Aerosil Co., Ltd.), RX-50 (manufactured by Nippon Aerosil Co., Ltd.), Sicastar 43-00-501 (manufactured by MicroMod Automation), and NSS-5N (manufactured by Tokuyama Corporation) can also be used.

(Flexibility-Imparting Agent (D))

The thermal conductive resin composition (P) according to the present embodiment may further include at least one flexibility-imparting agent (D) selected from a phenoxy resin and an epoxy resin in a liquid form at 25° C. and preferably includes both a phenoxy resin and an epoxy resin in a liquid form at 25° C. In such a case, it is possible to improve the flexibility and the flex resistance of thermal conductive sheets, and thus it is possible to further suppress the handling properties of thermal conductive sheets being degraded by the tight packing of the thermal conductive filler (B).

In addition, when the thermal conductive resin composition further includes the flexibility-imparting agent (D), it becomes possible to degrade the elastic modulus of thermal conductive sheet cured substances to be obtained, and, in this case, it is possible to improve the stress relaxation capability of thermal conductive sheet cured substances.

In addition, when the thermal conductive resin composition further includes the flexibility-imparting agent (D), it is possible to suppress the generation of voids and the like in thermal conductive sheet cured substances to be obtained, easily adjust the thickness of thermal conductive sheets to be obtained, or improve the uniformity of the thickness of thermal conductive sheets. In addition, it is possible to improve the adhesiveness between thermal conductive sheet cured substances and other members. With the above-described synergetic effect, it is possible to further enhance the insulation reliability of semiconductor devices to be obtained.

Examples of the epoxy resin in a liquid form at 25° C. include bisphenol A-type epoxy resins, bisphenol F-type epoxy resins, glycidyl amine-type epoxy resins, glycidyl ester-type epoxy resins, and the like. Among these, bisphenol A-type epoxy resins and bisphenol F-type epoxy resins are preferably used. In such a case, the handling properties of thermal conductive sheets further improve, it is possible to more easily carry out alignment when thermal conductive sheets are applied to semiconductor devices, and it is possible to improve the adhesiveness of thermal conductive sheets to other members and, furthermore, the mechanical characteristics of thermal conductive sheets after being cured.

Examples of the phenoxy resin include phenoxy resins having a bisphenol skeleton, phenoxy resins having a naphthalene skeleton, phenoxy resins having an anthracene skeleton, phenoxy resins having a biphenyl skeleton, phenoxy resins having a bisphenolacetophenone skeleton, and the like. In addition, it is also possible to use phenoxy resins having a structure having a plurality of kinds of the above-described skeleton.

Among these, bisphenol A-type or bisphenol F-type phenoxy resins are preferably used. Phenoxy resins having both a bisphenol A skeleton and a bisphenol F skeleton may also be used.

The weight-average molecular weight of the phenoxy resin is not particularly limited, but is preferably equal to or more than 2.0×10⁴ and equal to or less than 8.0×10⁴.

Meanwhile, the weight-average molecular weight of the phenoxy resin is a polystyrene-equivalent value measured by means of gel permeation chromatography (GPC).

The content of the flexibility-imparting agent (D) in the thermal conductive resin composition (P) according to the present embodiment is preferably equal to or more than 1% by mass and equal to or less than 20% by mass and more preferably equal to or more than 2% by mass and equal to or less than 15% by mass with respect to 100% by mass of the total solid content of the thermal conductive resin composition (P).

(Curing Agent (E))

The thermal conductive resin composition (P) according to the present embodiment preferably further includes a curing agent (E).

As the curing agent (E), it is possible to use one or more selected from a curing catalyst (E-1) and a phenol-based curing agent (E-2).

Examples of the curing catalyst (E-1) include organic metal salts such as zinc naphthenate, cobalt naphthenate, tin octylate, cobalt octylate, cobalt (II) bisacetylacetonate, and cobalt (III) trisacetylacetonate; tertiary amines such as triethylamine, tributylamine, and 1,4-diazabicyclo[2.2.2]octane; imidazoles such as 2-phenyl-4-methylimidazole, 2-ethyl-4-methylimidazole, 2,4-diethylimidazole, 2-phenyl-4-methyl-5-hydroxyimidazole, and 2-phenyl-4,5-dihydroxymethylimidazole; organic phosphorus compounds such as triphenylphosphine, tri-p-tolylphosphine, tetraphenylphosphonium⋅tetraphenylborate, triphenylphosphine⋅triphenylborane, 1,2-bis-(diphenylphosphino)ethane; phenol compounds such as phenol, bisphenol A, and nonylphenol; organic acids such as acetic acid, benzoic acid, salicylic acid, and p-toluenesulfonic acid; and the like; and mixtures thereof. As the curing catalyst (E-1), one of these, including derivatives thereof, may be used singly or two or more of these, including derivatives thereof, may be jointly used.

The content of the curing catalyst (E-1) in the thermal conductive resin composition (P) according to the present embodiment is not particularly limited, but is preferably equal to or more than 0.001% by mass and equal to or less than 1% by mass with respect to 100% by mass of the total solid content of the thermal conductive resin composition (P).

In addition, examples of the phenol-based curing agent (E-2) include novolac-type phenolic resins such as phenol novolac resins, cresol novolac resins, naphthol novolac resins, aminotriazine novolac resins, novolac resins, and trisphenylmethane-type phenolic novolac resins; modified phenolic resins such as terpene-modified phenolic resins and dicyclopentadiene-modified phenolic resins; aralkyl-type resins such as phenol aralkyl resins having a phenylene skeleton and/or a biphenylene skeleton and naphthol aralkyl resins having a phenylene skeleton and/or a biphenylene skeleton; bisphenol compounds such as bisphenol A and bisphenol F; resol-type phenol resins; and the like, and one of these may be used singly or two or more of these may be jointly used.

Among these, from the viewpoint of improving the glass transition temperature and decreasing the linear expansion coefficient, the phenol-based curing agent (E-2) is preferably a novolac-type phenolic resin or a resol-type phenolic resin.

The content of the phenol-based curing catalyst (E-2) is not particularly limited, but is preferably equal to or more than 1% by mass and equal to or less than 30% by mass and more preferably equal to or more than 5% by mass and equal to or less than 15% by mass with respect to 100% by mass of the total solid content of the thermal conductive resin composition (P).

(Coupling Agent (F))

The thermal conductive resin composition (P) according to the present embodiment may further include a coupling agent (F).

The coupling agent (F) is capable of improving the wetting properties of the interface between the epoxy resin (A1) or the cyanate resin (A2) and the thermal conductive filler (B).

As the coupling agent (F), any coupling agents that are ordinarily used can be used, and specifically, one or more coupling agents selected from epoxysilane coupling agents, cationic silane coupling agents, aminosilane coupling agents, titanate-based coupling agents, and silicone oil-type coupling agents are preferably used.

The amount of the coupling agent (F) added is dependent on the specific surface area of the thermal conductive filler (B) and is thus not particularly limited, but is preferably equal to or more than 0.1% by mass and equal to or less than 10% by mass and particularly preferably equal to or more than 0.5% by mass and equal to or less than 7% by mass with respect to 100% by mass of the thermal conductive filler (B).

(Other Components)

The thermal conductive resin composition (P) according to the present embodiment may include an antioxidant, a leveling agent, and the like as long as the effects of the present invention are not impaired.

The planar shape of thermal conductive sheets that are formed of the thermal conductive resin composition (P) according to the present embodiment is not particularly limited, can be appropriately selected according to the shape of heat dissipation members, heat generation bodies, or the like, and can be, for example, set to a rectangular shape. The film thickness of thermal conductive sheet cured substances is preferably equal to or more than 50 μm and equal to or less than 250 μm. In such a case, it is possible to improve the mechanical strength or the thermal resistance and more effectively transfer heat from heat generation bodies to heat dissipation members. Furthermore, the balance between the heat dissipation properties and the insulation properties of thermal conductive materials is more favorable.

The thermal conductive resin composition (P) and the thermal conductive sheet according to the present embodiment can be produced, for example, as described below.

First, the respective components described above are added to a solvent, thereby obtaining a varnish-form resin composition. In the present embodiment, for example, after the epoxy resin (A1), the cyanate resin (A2), and the like are added to a solvent so as to produce a resin varnish, the thermal conductive filler (B) is added to the resin varnish, and the components are stirred using three rolls or the like, whereby a varnish-form resin composition can be obtained. In such a case, it is possible to disperse the thermal conductive filler (B) more uniformly in the epoxy resin (A1) and the cyanate resin (A2).

The solvent is not particularly limited, and examples thereof include methyl ethyl ketone, methyl isobutyl ketone, propylene glycol monomethyl ether, cyclohexanone, and the like.

Next, the varnish-form resin composition is aged, thereby obtaining the thermal conductive resin composition (P). The aging enables the improvement of the thermal conduction properties, the insulation properties, the flexibility, and the like of thermal conductive sheet cured substances to be obtained. This is assumed to be because the aging increases the affinity of the thermal conductive filler (B) to the epoxy resin (A1) and the cyanate resin (A2). The aging can be carried out under conditions of, for example, 30° C. to 80° C., 8 to 25 hours, preferably 12 to 24 hours, and 0.1 to 1.0 MPa.

Next, the varnish-form thermal conductive resin composition (P) is formed into a sheet shape, thereby forming a thermal conductive sheet. In the present embodiment, for example, the varnish-form thermal conductive resin composition (P) is applied onto a base material and then thermally treated and dried, whereby a thermal conductive sheet can be obtained. Examples of the base material include heat dissipation members or lead frames, metal foils such as copper foils or aluminum foils, resin films, and the like. In addition, the thermal treatment for drying the thermal conductive resin composition (P) is carried out under conditions of, for example, 80° C. to 150° C. and five minutes to one hour. The film thickness of the thermal conductive sheet is, for example, equal to or more than 60 μm and equal to or less than 500 μm.

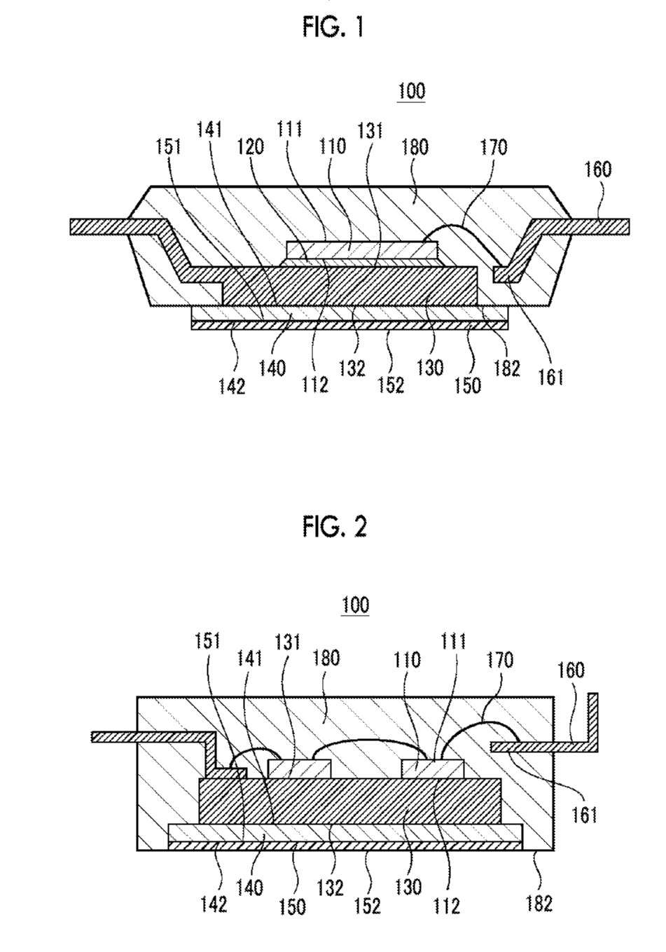

Next, a semiconductor device according to the present embodiment will be described. FIG. 1 is a cross-sectional view of a semiconductor device 100 according to an embodiment of the present invention.

Hereinafter, in order to simplify the description, the description will be made with an assumption that the positional relationships (the up and down relation and the like) of individual constituent elements of the semiconductor device 100 are as illustrated in individual drawings. However, the positional relationships in the description do not have any relationships with the positional relationships in the semiconductor device 100 during use or manufacture.

In the present embodiment, an example in which the metal plate is a heat sink will be described. The semiconductor device 100 according to the present embodiment includes a heat sink 130, a semiconductor chip 110 provided on a first surface 131 side of the heat sink 130, a thermal conductive material 140 joined to a second surface 132 of the heat sink 130 on a side opposite to the first surface 131, and an encapsulating resin 180 that encapsulates the semiconductor chip 110 and the heat sink 130. In addition, the thermal conductive material 140 is formed of the thermal conductive sheet according to the present embodiment.

Hereinafter, detailed description will be made.

The semiconductor device 100 has, for example, in addition to the above-described constitution, a conductive layer 120, a metal layer 150, leads 160, and a wire (metal wire) 170.

An electrode pattern, not illustrated, is formed on an upper surface 111 of the semiconductor chip 110, and a conductive pattern, not illustrated, is formed on a lower surface 112 of the semiconductor chip 110. The lower surface 112 of the semiconductor chip 110 is fixed to the first surface 131 of the heat sink 130 through a conductive layer 120 of silver paste or the like. The electrode pattern on the upper surface 111 of the semiconductor chip 110 is electrically connected to an electrode 161 of the lead 160 through the wire 170.

The heat sink 130 is constituted of metal.

The encapsulating resin 180 encapsulates, in addition to the semiconductor chip 110 and the heat sink 130, the wire 170, the conductive layer 120, and one part of each of the leads 160 in the encapsulating resin. The other part of each of the leads 160 protrudes to the outside of the encapsulating resin 180 from the side surface of the encapsulating resin 180. In the case of the present embodiment, for example, a lower surface 182 of the encapsulating resin 180 and the second surface 132 of the heat sink 130 are positioned on the same plane.

An upper surface 141 of the thermal conductive material 140 is attached to the second surface 132 of the heat sink 130 and the lower surface 182 of the encapsulating resin 180. That is, the encapsulating resin 180 is in contact with a surface of the thermal conductive material 140 on a heat sink 130 side (an upper surface 141) in the vicinity of the heat sink 130.

An upper surface 151 of the metal layer 150 is fixed to a lower surface 142 of the thermal conductive material 140. That is, one surface (the upper surface 151) of the metal layer 150 is fixed to a surface of the thermal conductive material 140 on a side opposite to the heat sink 130 side (the lower surface 142).

In a planar view, the visible outline of the upper surface 151 of the metal layer 150 and the visible outline of the surface of the thermal conductive material 140 on the side opposite to the heat sink 130 side (the lower surface 142) preferably overlap each other.

In addition, a surface of the metal layer 150 on a side opposite to the one surface (the upper surface 151) (a lower surface 152) is fully exposed from the encapsulating resin 180. Meanwhile, in the case of the present embodiment, as described above, the upper surface 141 of the thermal conductive material 140 is attached to the second surface 132 of the heat sink 130 and the lower surface 182 of the encapsulating resin 180, and thus the thermal conductive material 140 is exposed to the outside of the encapsulating resin 180 except for the upper surface 141. In addition, the metal layer 150 is fully exposed to the outside of the encapsulating resin 180.

Meanwhile, the second surface 132 and the first surface 131 of the heat sink 130 are formed to be, for example, flat respectively.

The mounting floor area of the semiconductor device 100 is not particularly limited and can be set to, as an example, equal to or more than 10×10 mm and equal to or less than 100×100 mm. Here, the mounting floor area of the semiconductor device 100 refers to the area of the lower surface 152 of the metal layer 150.

In addition, the number of the semiconductor chips 110 mounted on one heat sink 130 is not particularly limited and may be one or plural. For example, the number can be set to three or more (six or the like). That is, as an example, three or more semiconductor chips 110 may be provided on the first surface 131 side of one heat sink 130, and the encapsulating resin 180 may collectively encapsulate these three or more semiconductor chips 110.

The semiconductor device 100 is, for example, a power semiconductor device. This semiconductor device 100 can be provided with a 2-in-1 constitution in which two semiconductor chips 110 are encapsulated in the encapsulating resin 180, a 6-in-1 constitution in which six semiconductor chips 110 are encapsulated in the encapsulating resin 180, or a 7-in-1 constitution in which seven semiconductor chips 110 are encapsulated in the encapsulating resin 180.

Next, an example of the method for manufacturing the semiconductor device 100 according to the present embodiment will be described.

First, the heat sink 130 and the semiconductor chip 110 are prepared, and the lower surface 112 of the semiconductor chip 110 is fixed to the first surface 131 of the heat sink 130 through the conductive layer 120 of silver paste or the like.

Next, a lead frame including the leads 160 (all are not illustrated) is prepared, and the electrode pattern on the upper surface 111 of the semiconductor chip 110 and the electrode 161 in the lead 160 are electrically connected to each other through the wire 170.

Next, the semiconductor chip 110, the conductive layer 120, the heat sink 130, the wire 170, and a part of each of the leads 160 are collectively encapsulated with the encapsulating resin 180.

Next, the thermal conductive material 140 is prepared, and the upper surface 141 of the thermal conductive material 140 is attached to the second surface 132 of the heat sink 130 and the lower surface 182 of the encapsulating resin 180. Furthermore, the one surface (the upper surface 151) of the metal layer 150 is fixed to the surface of the thermal conductive material 140 on the side opposite to the heat sink 130 side (the lower surface 142). Meanwhile, before the thermal conductive material 140 is attached to the heat sink 130 and the encapsulating resin 180, the metal layer 150 may be fixed to the lower surface 142 of the thermal conductive material 140 in advance. Next, the respective leads 160 are cut from the frame body (not illustrated) of the lead frame. In the above-described manner, the semiconductor device 100 having a structure as illustrated in FIG. 1 is obtained.

According to the above-described embodiment, the semiconductor device 100 includes the heat sink 130, the semiconductor chip 110 provided on the first surface 131 side of the heat sink 130, the insulating thermal conductive material 140 attached to the second surface 132 of the heat sink 130 on the side opposite to the first surface 131, and the encapsulating resin 180 that encapsulates the semiconductor chip 110 and the heat sink 130.

As described above, in a case in which the package of the semiconductor device is smaller than a certain degree, even when the deterioration of the insulation properties of the thermal conductive material does not become evident as a problem, the electric field in the place in which the electric field concentrates the most in the surface of the thermal conductive material becomes stronger as the area of the package of the semiconductor device increases. Therefore, it is considered that there is a possibility that the deterioration of the insulation properties caused by slight changes in the film thickness of the thermal conductive material also becomes evident as a problem.

In contrast, the semiconductor device 100 according to the present embodiment can be expected to obtain sufficient insulation reliability by including the thermal conductive material 140 having the above-described structure even when the semiconductor device is a large-size package having amounting floor area of equal to or more than 10×10 mm and equal to or less than 100×100 mm.

In addition, the semiconductor device 100 according to the present embodiment can be expected to obtain sufficient insulation reliability by including the thermal conductive material 140 having the above-described structure even when the semiconductor device is provided with a structure in which, for example, three or more semiconductor chips 110 are provided on the first surface 131 side of one heat sink 130, and these three or more semiconductor chips are collectively encapsulated with the encapsulating resin 180, that is, the semiconductor device 100 is a large-size package.

In addition, in a case in which the semiconductor device 100 further includes the metal layer 150 having one surface (the upper surface 151) fixed to the surface of the thermal conductive material 140 on the side opposite to the heat sink 130 side (the lower surface 142), it is possible to preferably dissipate heat using this metal layer 150, and thus the heat dissipation properties of the semiconductor device 100 improve.

In addition, when the upper surface 151 of the metal layer 150 is smaller than the lower surface 142 of the thermal conductive material 140, a concern of the exposure of the lower surface 142 of the thermal conductive material 140 to the outside and the generation of cracks in the thermal conductive material 140 by protruding objects such as foreign substances is generated. On the other hand, when the upper surface 151 of the metal layer 150 is larger than the lower surface 142 of the thermal conductive material 140, the end portions of the metal layer 150 have a shape in which the end portions float in the air, and there is a possibility that the metal layer 150 may be peeled off while being handled in manufacturing processes.

In contrast, in a planar view, when the visible outline of the upper surface 151 of the metal layer 150 and the visible outline of the lower surface 142 of the thermal conductive material 140 overlap each other, it is possible to suppress the generation of cracks in the thermal conductive material 140 and the peeling of the metal layer 150.

In addition, since the lower surface 152 of the metal layer 150 is fully exposed from the encapsulating resin 180, it becomes possible to dissipate heat on the entire lower surface 152 of the metal layer 150, and favorable heat dissipation properties of the semiconductor device 100 are obtained.

FIG. 2 is a cross-sectional view of the semiconductor device 100 according to an embodiment of the present invention. This semiconductor device 100 is different from the semiconductor device 100 illustrated in FIG. 1 in terms of facts described below and is constituted in the same manner as the semiconductor device 100 illustrated in FIG. 1 in terms of the other facts.

In the case of the present embodiment, the thermal conductive material 140 is encapsulated in the encapsulating resin 180. In addition, the metal layer 150 is also encapsulated in the encapsulating resin 180 except for the lower surface 152. In addition, the lower surface 152 of the metal layer 150 and the lower surface 182 of the encapsulating resin 180 are positioned on the same plane.

Meanwhile, FIG. 2 illustrates an example in which at least two semiconductor chips 110 are mounted on the first surface 131 of the heat sink 130. Electrode patterns on the upper surfaces 111 of these semiconductor chips 110 are electrically connected to each other through a wire 170. On the first surface 131, for example, a total of six semiconductor chips 110 are mounted. That is, for example, three rows of two semiconductor chips 110 are disposed in a direction toward the back of FIG. 2.

Meanwhile, when the semiconductor device 100 illustrated in FIG. 1 or FIG. 2 is mounted on a substrate (not illustrated), a power module including the substrate and the semiconductor device 100 is obtained.

[Second Invention] Hereinafter, an embodiment according to a second invention will be described.

First, a thermal conductive resin composition (P) according to the present embodiment will be described.

The thermal conductive resin composition (P) according to the present invention includes an epoxy resin (A1), a thermal conductive filler (B), and silica nanoparticles (C).

In addition, the average particle diameter D₅₀ of the silica nanoparticles (C) which is measured using a dynamic light scattering method is equal to or more than 1 nm and equal to or less than 100 nm, the content of the silica nanoparticles (C) is equal to or more than 0.3% by mass and equal to or less than 2.5% by mass with respect to 100% by mass of the total solid content of the thermal conductive resin composition (P), and the thermal conductive filler (B) includes secondary agglomerated particles constituted of the primary particles of scale-like boron nitride.

According to the present embodiment, due to the above-described constitution, it is possible to obtain the thermal conductive resin composition (P) having excellent preservation stability.

Meanwhile, in the present embodiment, the thermal conductive resin composition (P) in a B-stage state which has a sheet shape and is formed by semi-curing the thermal conductive resin composition (P) will be referred to as “thermal conductive sheet”. In addition, a substance obtained by curing the thermal conductive sheet will be referred to as “thermal conductive sheet cured substance”. In addition, the thermal conductive sheet which is applied to semiconductor devices and is cured will be referred to as “thermal conductive material”.

The thermal conductive material is provided in, for example, a joint interface in which high thermal conduction properties in semiconductor devices are required and accelerates thermal conduction from heat generation bodies to heat dissipation bodies. Therefore, faults attributed to characteristic alteration in semiconductor chips and the like are suppressed, and the stability of semiconductor devices can be improved.

An example of semiconductor devices to which the thermal conductive sheet according to the present invention is applied is a structure in which, for example, a semiconductor chip is provided on a heat sink (metal plate), and the thermal conductive material is provided on the surface of the heat sink on a side opposite to the surface to which the semiconductor chip is joined.

In addition, another example of semiconductor devices to which the thermal conductive sheet according to the present invention is applied is a semiconductor device including the thermal conductive material, a semiconductor chip joined to one surface of the thermal conductive material, a metal member joined to the surface of the thermal conductive material on a side opposite to the above-described surface, and an encapsulating resin that encapsulates the thermal conductive material, the semiconductor chip, and the metal member.

According to the present inventors' studies, it has been clarified that, in resin varnish of the related art which is used to form thermal conductive materials constituting semiconductor devices, thermal conductive fillers easily settle, and thus there is room for the improvement of preservation stability.

Therefore, as a result of intensive studies in consideration of the above-described circumstances, the present inventors found that, when a combination of the epoxy resin (A1) and the thermal conductive filler (B) including secondary agglomerated particles constituted of the primary particles of scale-like boron nitride is added to the thermal conductive resin composition (P), and furthermore, a specific amount of the silica nanoparticles (C) having an average particle diameter D₅₀ in a specific range are added thereto, thermal conductive resin compositions having excellent preservation stability are obtained.

In the thermal conductive resin composition (P) according to the present embodiment, the glass transition temperature of cured substances of the thermal conductive resin composition (P), which is measured by a dynamic mechanical analysis under conditions of a temperature-increase rate of 5° C./min and a frequency of 1 Hz, is preferably equal to or higher than 175° C. and more preferably equal to or higher than 190° C. The upper limit value of the glass transition temperature is not particularly limited and is, for example, equal to or lower than 300° C.

Here, the glass transition temperature of cured substances of the thermal conductive resin composition (P) can be measured, for example, as described below. First, the thermal conductive resin composition (P) is thermally treated at 100° C. for 30 minutes, thereby producing a B-stage-form thermal conductive sheet having a film thickness of 400 μm. Next, the thermal conductive sheet is thermally treated at 180° C. and 10 MPa for 40 minutes, thereby obtaining a thermal conductive sheet cured substance. Next, the glass transition temperature (Tg) of the obtained cured substance is measured by the dynamic mechanical analysis (DMA) under conditions of a temperature-increase rate of 5° C./min and a frequency of 1 Hz.

When the glass transition temperature is equal to or higher than the lower limit value, it is possible to further suppress the motion opening of conductive components, and thus it is possible to further suppress the insulation properties of the cured substance being degraded by an increase in temperature. As a result, it is possible to realize semiconductor devices having more favorable insulation reliability.

The glass transition temperature can be controlled by appropriately adjusting the kinds or blending ratios of the respective components constituting the thermal conductive resin composition (P) and the method for preparing the thermal conductive resin composition (P).

In the thermal conductive resin composition (P) according to the present embodiment, the storage elastic modulus E′ at 50° C. of cured substances of the thermal conductive resin composition (P) is preferably equal to or more than 12 GPa and equal to or less than 50 GPa and more preferably equal to or more than 15 GPa and equal to or less than 35 GPa.

When the storage elastic modulus E′ is in the above-described range, the stiffness of cured substances to be obtained becomes appropriate, and, even in a case in which ambient temperature changes, it is possible to stably relax stress which is generated between members due to the difference in linear expansion coefficient in the cured substances. Therefore, it is possible to further enhance the joint reliability between individual members.

Here, the storage elastic modulus E′ at 50° C. can be measured, for example, as described below. First, the thermal conductive resin composition (P) is thermally treated at 100° C. for 30 minutes, thereby producing a B-stage-form thermal conductive sheet having a film thickness of 400 μm. Next, the thermal conductive sheet is thermally treated at 180° C. and 10 MPa for 40 minutes, thereby obtaining a thermal conductive sheet cured substance. Next, the storage elastic modulus E′ at 50° C. of the obtained cured substance is measured by a dynamic mechanical analysis (DMA). Here, the storage elastic modulus E′ is the value of the storage elastic modulus E′ at 50° C. which is measured from 25° C. to 300° C. at a frequency of 1 Hz and a temperature-increase rate of 5 to 10° C./minute after a tensile load is applied to the thermal conductive sheet cured substance.

The storage elastic modulus E′ at 50° C. of the cured substance of the thermal conductive resin composition (P) according to the present embodiment can be controlled by appropriately adjusting the kinds or blending ratios of the respective components constituting the thermal conductive resin composition (P) according to the present embodiment and the method for preparing the thermal conductive resin composition (P).

In the thermal conductive resin composition (P) according to the present embodiment, from the viewpoint of further improving the heat dissipation properties of thermal conductive sheet cured substances to be obtained, the thermal conductivity at 25° C., which is measured by the following thermal conductivity test, is preferably equal to or more than 3 W/(m·K) and more preferably equal to or more than 10 W/(m·K).

<Thermal Conductivity Test>

The thermal conductive resin composition (P) is thermally treated at 100° C. for 30 minutes, thereby producing a B-stage-form thermal conductive sheet having a film thickness of 400 μm. Next, the thermal conductive sheet is thermally treated at 180° C. and 10 MPa for 40 minutes, thereby obtaining a thermal conductive sheet cured substance. Next, the thermal conductivity of the thermal conductive sheet cured substance in the thickness direction is measured using a laser flash method.

In the thermal conductive resin composition (P) according to the present embodiment, the volume resistivity at 175° C. of the cured substance of the thermal conductive resin composition (P), which is on the basis of JIS K6911 and is measured one minute after the application of a voltage at an applied voltage of 1,000 V, is preferably equal to or more than 1.0×10⁹ Ω·m and more preferably equal to or more than 1.0×10¹⁰ Ω·m. The upper limit value of the volume resistivity at 175° C. is not particularly limited and is, for example, 1.0×10¹³ Ω·m.

Here, the volume resistivity at 175° C. of the cured substance of the thermal conductive resin composition (P) can be measured, for example, as described below. First, the thermal conductive resin composition (P) is thermally treated at 100° C. for 30 minutes, thereby producing a B-stage-form thermal conductive sheet having a film thickness of 400 μm. Next, the thermal conductive sheet is thermally treated at 180° C. and 10 MPa for 40 minutes, thereby obtaining a thermal conductive sheet cured substance. Next, the volume resistivity of the obtained cured substance is measured one minute after the application of a voltage at an applied voltage of 1,000 V on the basis of JIS K6911.

Here, the volume resistivity at 175° C. represents an index of the insulation properties at high temperatures of the thermal conductive sheet cured substance. That is, as the volume resistivity at 175° C. increases, the insulation properties at high temperatures become more favorable.

The volume resistivity at 175° C. of the cured substance of the thermal conductive resin composition (P) according to the present embodiment can be controlled by appropriately adjusting the kinds or blending ratios of the respective components constituting the thermal conductive resin composition (P) according to the present embodiment and the method for preparing the thermal conductive resin composition (P).

Thermal conductive materials formed of the thermal conductive resin composition (P) according to the present embodiment are provided, for example, between heat generation bodies such as semiconductor chips and substrates on which the heat generation bodies are mounted such as lead frames or wiring substrates (interposers) or between the substrates and heat dissipation members such as heat sinks. Therefore, it is possible to maintain the insulation properties of semiconductor devices and effectively dissipate heat generated from the heat generation bodies to the outside of semiconductor devices. Therefore, it becomes possible to improve the reliability of semiconductor devices.

Hereinafter, the respective components constituting the thermal conductive resin composition (P) will be described.

The thermal conductive resin composition (P) according to the present embodiment includes the epoxy resin (A1), the thermal conductive filler (B), and the silica nanoparticles (C).

(Epoxy Resin (A1))

Examples of the epoxy resin (A1) include bisphenol-type epoxy resins such as bisphenol A-type epoxy resins, bisphenol F-type epoxy resins, bisphenol E-type epoxy resins, bisphenol S-type epoxy resins, bisphenol M-type epoxy resins (4,4′-(1,3-phenylenediisopridien) bisphenol-type epoxy resin), bisphenol P-type epoxy resins (4,4′-(1,4-phenylenediisopridien) bisphenol-type epoxy resin), bisphenol Z-type epoxy resins (4,4′-cyclohexadiene bisphenol-type epoxy resin); novolac-type epoxy resins such as phenol novolac-type epoxy resins, cresol novolac-type epoxy resins, tetraphenol group ethane-type novolac-type epoxy resins, and novolac-type epoxy resins having a condensed ring aromatic hydrocarbon structure; epoxy resins having a biphenyl skeleton; arylalkylene-type epoxy resins such as xylylene-type epoxy resins and epoxy resins having a biphenyl aralkyl skeleton; naphthalene-type epoxy resins such as naphthylene ether-type epoxy resins, naphthol-type epoxy resins, naphthalene diol-type epoxy resins, bifunctional or tetrafunctional epoxy-type naphthalene resins, binaphthyl-type epoxy resins, and epoxy resins having a naphthalene aralkyl skeleton; anthracene-type epoxy resins; phenoxy-type epoxy resins; epoxy resins having a dicyclopentadiene skeleton; norbornene-type epoxy resins; epoxy resins having an adamantane skeleton; fluorene-type epoxy resins; epoxy resin having a phenol aralkyl skeleton; and the like.

Meanwhile, in the present embodiment, epoxy resins in a liquid form at 25° C. which will be described below are not included in the scope of the epoxy resin (A1).

Among these, the epoxy resin (A1) is preferably an epoxy resin having a dicyclopentadiene skeleton, an epoxy resin having an adamantane skeleton, an epoxy resin having a phenol aralkyl skeleton, an epoxy resin having a biphenyl aralkyl skeleton, an epoxy resin having a naphthalene aralkyl skeleton, or the like.

As the epoxy resin (A1), one of these resins may be used singly or two or more resins may be jointly used.

When the above-described epoxy resin (A1) is used, the glass transition temperature of the thermal conductive sheet cured substance increases, and it is possible to improve the heat dissipation properties and the insulation properties of the thermal conductive sheet cured substance.

The content of the epoxy resin (A1) in the thermal conductive resin composition (P) according to the present embodiment is preferably equal to or more than 0.5% by mass and equal to or less than 15% by mass and more preferably equal to or more than 1% by mass and equal to or less than 12% by mass with respect to 100% by mass of the total solid content of the thermal conductive resin composition (P). When the content of the epoxy resin (A1) is equal to or more than the lower limit value, the content of the cyanate resin (A2) relatively decreases, and there are cases in which the moisture resistance improves. When the content of the epoxy resin (A1) is equal to or less than the upper limit value, the handling properties improve, and it becomes easy to form the thermal conductive sheet cured substance.

Meanwhile, in the present embodiment, the total solid content of the thermal conductive resin composition (P) refers to components remaining in a solid content form when the thermal conductive resin composition (P) is heated and cured, and, for example, components that are volatilized by heating such as solvents are not included in the scope of the total solid content. Meanwhile, epoxy resins in a liquid form at 25° C. and liquid-form components such as coupling agents are incorporated into the solid content of the thermal conductive resin composition (P) when heated and cured and are thus included in the scope of the total solid content.

{Cyanate Resin (A2)}

From the viewpoint of improving the insulation properties of thermal conductive sheet cured substances to be obtained, the thermal conductive resin composition (P) according to the present embodiment may further include the cyanate resin (A2). Examples of the cyanate resin (A2) include the same resins exemplified in the first invention. Here, the description thereof will not be repeated.

The content of the cyanate resin (A2) in the thermal conductive resin composition (P) according to the present embodiment is preferably equal to or more than 2% by mass and equal to or less than 25% by mass and more preferably equal to or more than 5% by mass and equal to or less than 20% by mass with respect to 100% by mass of the total solid content of the thermal conductive resin composition (P). When the content of the cyanate resin (A2) is equal to or more than the lower limit value, the insulation properties of thermal conductive sheet cured substances to be obtained further improve, and it is possible to improve the flexibility and the flex resistance of thermal conductive sheets to be obtained, and thus it is possible to suppress the handling properties of thermal conductive sheets being degraded by the tight packing of the thermal conductive filler (B). When the content of the cyanate resin (A2) is equal to or less than the upper limit value, there are cases in which the moisture resistance of thermal conductive sheet cured substances to be obtained improves.

In addition, the total content of the epoxy resin (A1) and the cyanate resin (A2) in the thermal conductive resin composition (P) according to the present embodiment is preferably equal to or more than 5% by mass and equal to or less than 40% by mass and more preferably equal to or more than 9% by mass and equal to or less than 30% by mass with respect to 100% by mass of the total solid content of the thermal conductive resin composition (P). When the total content of the epoxy resin (A1) and the cyanate resin (A2) is equal to or more than the lower limit value, the handling properties of thermal conductive sheet cured substances improve, and it becomes easy to form thermal conductive sheet cured substances. When the total content of the epoxy resin (A1) and the cyanate resin (A2) is equal to or less than the upper limit value, the strength or the flame resistance of thermal conductive sheet cured substances further improves or the thermal conduction properties of thermal conductive sheet cured substances further improves.

(Thermal Conductive Filler (B))

Examples of the thermal conductive filler (B) include alumina, boron nitride, aluminum nitride, silicon nitride, silicon carbide, and the like. As the thermal conductive filler, one filler may be used singly or two or more fillers may be jointly used.

From the viewpoint of improving the thermal conduction properties of the thermal conductive sheet cured substance according to the present embodiment, as the thermal conductive filler (B), the thermal conductive resin composition includes secondary agglomerated particles that are formed by agglomerating the primary particles of scale-like boron nitride.

The secondary agglomerated particles that are formed by agglomerating the primary particles of scale-like boron nitride can be formed by, for example, agglomerating scale-like boron nitride using a spray drying method or the like and then firing the boron nitride. The firing temperature is, for example, 1,200° C. to 2,500° C.

In a case in which the secondary agglomerated particles that are obtained by firing scale-like boron nitride are used as described above, from the viewpoint of improving the dispersibility of the thermal conductive filler (B) in the epoxy resin (A1), the epoxy resin (A1) is particularly preferably an epoxy resin having a dicyclopentadiene skeleton.

The average particle diameter of the secondary agglomerated particles that are formed by agglomerating scale-like boron nitride is, for example, preferably equal to or more than 5 μm and equal to or less than 180 μm and more preferably equal to or more than 10 μm and equal to or less than 100 μm. In such a case, it is possible to realize thermal conductive sheet cured substances being more favorable in terms of the balance between the thermal conduction properties and the insulation properties.

The average long diameter of the primary particles of scale-like boron nitride which constitute the secondary agglomerated particles is preferably equal to or more than 0.01 μm and equal to or less than 40 μm and more preferably equal to or more than 0.1 μm and equal to or less than 20 μm. In such a case, it is possible to realize thermal conductive sheet cured substances being more favorable in terms of the balance between the thermal conduction properties and the insulation properties.

Meanwhile, this average long diameter can be measured using electron microscope photographs. For example, the average long diameter is measured in the following order. First, samples are produced by cutting the secondary agglomerated particles using a microtome or the like. Next, several cross-sectional photographs of the secondary agglomerated particles magnified to several thousand times are captured using a scanning electron microscope. Next, arbitrary secondary agglomerated particles are selected, and the long diameters of the primary particles of the scale-like boron nitride are measured from the photographs. At this time, the long diameters of ten or more primary particles are measured, and the average value thereof is considered as the average long diameter.

The content of the thermal conductive filler (B) in the thermal conductive resin composition (P) according to the present embodiment is preferably equal to or more than 50% by mass and equal to or less than 92% by mass, more preferably equal to or more than 55% by mass and equal to or less than 88% by mass, and particularly preferably equal to or more than 60% by mass and equal to or less than 85% by mass with respect to 100% by mass of the total solid content of the thermal conductive resin composition (P).

When the content of the thermal conductive filler (B) is equal to or more than the lower limit value, it is possible to more effectively improve the thermal conduction properties or the mechanical strength of thermal conductive sheet cured substances to be obtained. Meanwhile, when the content of the thermal conductive filler (B) is equal to or less than the upper limit value, the film formation properties or the workability of the thermal conductive resin composition (P) are improved, and it is possible to further improve the uniformity of the film thickness of thermal conductive sheets to be obtained.

From the viewpoint of further improving the thermal conduction properties of thermal conductive sheet cured substances, the thermal conductive filler (B) according to the present embodiment preferably further includes, in addition to the secondary agglomerated particles, the primary particles of scale-like boron nitride which are different from the primary particles of scale-like boron nitride which constitute the secondary agglomerated particles. The average long diameter of the primary particles of scale-like boron nitride is preferably equal to or more than 0.01 μm and equal to or less than 40 μm and more preferably equal to or more than 0.1 μm and equal to or less than 30 μm.

In such a case, it is possible to realize thermal conductive sheet cured substances being more favorable in terms of the balance between the thermal conduction properties and the insulation properties.

From the viewpoint of suppressing the settlement of the thermal conductive filler (B) in varnish-form thermal conductive resin compositions (P) and improving the preservation stability of the thermal conductive resin composition (P), the thermal conductive resin composition (P) according to the present embodiment includes silica nanoparticles (C).

The average particle diameter D₅₀ of the silica nanoparticles (C) which is measured using a dynamic light scattering method is equal to or more than 1 nm and equal to or less than 100 nm, preferably equal to or more than 10 nm and equal to or less than 100 nm, and particularly preferably equal to or more than 10 nm and equal to or less than 70 nm. When the average particle diameter D₅₀ of the silica nanoparticles (C) is in the above-described range, it is possible to further suppress the settlement of the thermal conductive filler (B) in varnish-form thermal conductive resin compositions (P).

Meanwhile, the average particle diameter of the silica nanoparticles (C) can be measured using, for example, a dynamic light scattering method. The particles are dispersed in water using ultrasonic waves, the volume-based particle size distribution of the particles is measured using a dynamic light scattering method-type particle size distribution measurement instrument (manufactured by Horiba, Ltd., LB-550), and the median diameter (D₅₀) is considered as the average particle diameter.

In addition, the content of the silica nanoparticles (C) is equal to or more than 0.3% by mass and equal to or less than 2.5% by mass, preferably equal to or more than 0.4% by mass and equal to or less than 2.0% by mass, and more preferably equal to or more than 0.5% by mass and equal to or less than 1.8% by mass with respect to 100% by mass of the total solid content of the thermal conductive resin composition (P).

When the content of the silica nanoparticles (C) is in the above-described range, the settlement of the thermal conductive filler (B) in varnish-form thermal conductive resin compositions (P) is suppressed, and it is possible to further improve the handling properties and the preservation stability of the thermal conductive resin composition (P).

The method for manufacturing the silica nanoparticles (C) is not particularly limited, examples thereof include combustion methods such as a vaporized metal combustion (VMC) method and a physical vapor synthesis (PVS) method, melting methods in which crushed silica is flame-melted, settlement methods, gel methods, and the like, and, among these, the VMC method is particularly preferred.

The VMC method refers to a method in which silicon powder is injected into chemical flame formed in oxygen-containing gas, combusted, and then cooled, thereby forming silica particles. In the VMC method, the particle diameters of silica particles to be obtained can be adjusted by adjusting the particle diameters and injection amount of silicon powder to be injected, the flame temperature, and the like, and thus it is possible to manufacture silica particles having different particle diameters.

As the silica nanoparticles (C), commercially available products such as RX-200 (manufactured by Nippon Aerosil Co., Ltd.), RX-50 (manufactured by Nippon Aerosil Co., Ltd.), NSS-5N (manufactured by Tokuyama Corporation), and Sicastar 43-00-501 (manufactured by MicroMod Automation) can also be used.

(Flexibility-Imparting Agent (D))

The thermal conductive resin composition (P) according to the present embodiment may further include at least one flexibility-imparting agent (D) selected from a phenoxy resin and an epoxy resin in a liquid form at 25° C. and preferably includes both a phenoxy resin and an epoxy resin in a liquid form at 25° C. In such a case, it is possible to improve the flexibility and the flex resistance of thermal conductive sheets, and thus it is possible to suppress the handling properties of thermal conductive sheets being degraded by the tight packing of the thermal conductive filler (B).

In addition, when the thermal conductive resin composition further includes the flexibility-imparting agent (D), it becomes possible to degrade the elastic modulus of thermal conductive sheet cured substances to be obtained, and, in this case, it is possible to improve the stress relaxation capability of thermal conductive sheet cured substances.

In addition, when the thermal conductive resin composition further includes the flexibility-imparting agent (D), it is possible to suppress the generation of voids and the like in thermal conductive sheet cured substances to be obtained, easily adjust the thickness of thermal conductive sheets to be obtained, or improve the uniformity of the thickness of thermal conductive sheets. In addition, it is possible to improve the adhesiveness between thermal conductive sheet cured substances and other members. With the above-described synergetic effect, it is possible to further enhance the insulation reliability of semiconductor devices to be obtained.

Examples of the phenoxy resin and the epoxy resin in a liquid form at 25° C. include the same resins exemplified in the first invention. Here, the description thereof will not be repeated.

The content of the flexibility-imparting agent (D) in the thermal conductive resin composition (P) according to the present embodiment is preferably equal to or more than 1% by mass and equal to or less than 20% by mass and more preferably equal to or more than 2% by mass and equal to or less than 15% by mass with respect to 100% by mass of the total solid content of the thermal conductive resin composition (P).

(Curing Agent (E))

The thermal conductive resin composition (P) according to the present embodiment preferably further includes a curing agent (E).

As the curing agent (E), it is possible to use one or more selected from a curing catalyst (E-1) and a phenol-based curing agent (E-2).

Examples of the curing catalyst (E-1) include organic metal salts such as zinc naphthenate, cobalt naphthenate, tin octylate, cobalt octylate, cobalt (II) bisacetylacetonate, and cobalt (III) trisacetylacetonate; tertiary amines such as triethylamine, tributylamine, and 1,4-diazabicyclo[2.2.2]octane; imidazoles such as 2-phenyl-4-methylimidazole, 2-ethyl-4-methylimidazole, 2,4-diethylimidazole, 2-phenyl-4-methyl-5-hydroxyimidazole, and 2-phenyl-4,5-dihydroxymethylimidazole; organic phosphorus compounds such as triphenylphosphine, tri-p-tolylphosphine, tetraphenylphosphonium⋅tetraphenylborate, triphenylphosphine⋅triphenylborane, 1,2-bis-(diphenylphosphino)ethane; phenol compounds such as phenol, bisphenol A, and nonylphenol; organic acids such as acetic acid, benzoic acid, salicylic acid, and p-toluenesulfonic acid; and the like; and mixtures thereof. As the curing catalyst (E-1), one of these, including derivatives thereof, may be used singly or two or more of these, including derivatives thereof, may be jointly used. The content of the curing catalyst (E-1) in the thermal conductive resin composition (P) according to the present embodiment is not particularly limited, but is preferably equal to or more than 0.001% by mass and equal to or less than 1% by mass with respect to 100% by mass of the total solid content of the thermal conductive resin composition (P).

In addition, examples of the phenol-based curing agent (E-2) include novolac-type phenolic resins such as phenol novolac resins, cresol novolac resins, naphthol novolac resins, aminotriazine novolac resins, novolac resins, and trisphenylmethane-type phenolic novolac resins; modified phenolic resins such as terpene-modified phenolic resins and dicyclopentadiene-modified phenolic resins; aralkyl-type resins such as phenol aralkyl resins having a phenylene skeleton and/or a biphenylene skeleton and naphthol aralkyl resins having a phenylene skeleton and/or a biphenylene skeleton; bisphenol compounds such as bisphenol A and bisphenol F; resol-type phenol resins; and the like, and one of these may be used singly or two or more of these may be jointly used.

Among these, from the viewpoint of improving the glass transition temperature and decreasing the linear expansion coefficient, the phenol-based curing agent (E-2) is preferably a novolac-type phenolic resin or a resol-type phenolic resin.

The content of the phenol-based curing catalyst (E-2) is not particularly limited, but is preferably equal to or more than 1% by mass and equal to or less than 30% by mass and more preferably equal to or more than 5% by mass and equal to or less than 15% by mass with respect to 100% by mass of the total solid content of the thermal conductive resin composition (P).

(Coupling Agent (F))

The thermal conductive resin composition (P) according to the present embodiment may further include a coupling agent (F).

The coupling agent (F) is capable of improving the wetting properties of the interface between the epoxy resin (A1) or the cyanate resin (A2) and the thermal conductive filler (B).

As the coupling agent (F), any coupling agents that are ordinarily used can be used, and specifically, one or more coupling agents selected from epoxysilane coupling agents, cationic silane coupling agents, aminosilane coupling agents, titanate-based coupling agents, and silicone oil-type coupling agents are preferably used.

The amount of the coupling agent (F) added is dependent on the specific surface area of the thermal conductive filler (B) and is thus not particularly limited, but is preferably equal to or more than 0.1% by mass and equal to or less than 10% by mass and particularly preferably equal to or more than 0.5% by mass and equal to or less than 7% by mass with respect to 100% by mass of the thermal conductive filler (B).

(Other Components)

The thermal conductive resin composition (P) according to the present embodiment may include an antioxidant, a leveling agent, and the like as long as the effects of the present invention are not impaired.

The planar shape of thermal conductive sheets that are formed of the thermal conductive resin composition (P) according to the present embodiment is not particularly limited, can be appropriately selected according to the shape of heat dissipation members, heat generation bodies, or the like, and can be, for example, set to a rectangular shape. The film thickness of thermal conductive sheet cured substances is preferably equal to or more than 50 μm and equal to or less than 250 μm. In such a case, it is possible to improve the mechanical strength or the thermal resistance and more effectively transfer heat from heat generation bodies to heat dissipation members. Furthermore, the balance between the heat dissipation properties and the insulation properties of thermal conductive materials is more favorable.

The thermal conductive resin composition (P) and the thermal conductive sheet according to the present embodiment can be produced, for example, as described below.

First, the respective components described above are added to a solvent, thereby obtaining a varnish-form resin composition. In the present embodiment, for example, after the epoxy resin (A1) and the like are added to a solvent so as to produce a resin varnish, the thermal conductive filler (B) and the silica nanoparticles (C) are added to the resin varnish, and the components are stirred using three rolls or the like, whereby a varnish-form resin composition can be obtained. In such a case, it is possible to disperse the thermal conductive filler (B) and the silica nanoparticles (C) more uniformly in the epoxy resin (A1).

The solvent is not particularly limited, and examples thereof include methyl ethyl ketone, methyl isobutyl ketone, propylene glycol monomethyl ether, cyclohexanone, and the like.

Next, the varnish-form resin composition is aged, thereby obtaining the thermal conductive resin composition (P). The aging enables the improvement of the thermal conduction properties, the insulation properties, the flexibility, and the like of thermal conductive sheet cured substances to be obtained. This is assumed to be because the aging increases the affinity of the thermal conductive filler (B) and the silica nanoparticles (C) to the epoxy resin (A1). The aging can be carried out under conditions of, for example, 30° C. to 80° C., 8 to 25 hours, preferably 12 to 24 hours, and 0.1 to 1.0 MPa.

Next, the varnish-form thermal conductive resin composition (P) is formed into a sheet shape, thereby forming a thermal conductive sheet. In the present embodiment, for example, the varnish-form thermal conductive resin composition (P) is applied onto a base material and then thermally treated and dried, whereby a thermal conductive sheet can be obtained. Examples of the base material include heat dissipation members or lead frames, metal foils such as copper foils or aluminum foils, resin films, and the like. In addition, the thermal treatment for drying the thermal conductive resin composition (P) is carried out under conditions of, for example, 80° C. to 150° C. and five minutes to one hour. The film thickness of the thermal conductive sheet is, for example, equal to or more than 60 μm and equal to or less than 500 μm.

A semiconductor device according to the present embodiment is the same as the semiconductor device according to the first invention described above except for the fact that the thermal conductive material 140 is formed of the thermal conductive sheet according to the present embodiment.

Meanwhile, the present invention is not limited to the above-described embodiments, and modifications, improvements, and the like are included in the scope of the present invention as long as the object of the present invention can be achieved.

### EXAMPLES

### Examples and Comparative Examples of First Invention

Hereinafter, the first invention will be described using examples and comparative examples, but the first invention is not limited thereto. Meanwhile, in the examples and the comparative examples, unless particularly described otherwise, ‘parts’ indicates “parts by mass”. In addition, individual thicknesses indicate average film thicknesses.

(Production Example of Thermal Conductive Filler)

A mixture obtained by mixing melamine borate and scale-like boron nitride powder (average long diameter: 15 μm) was added to an aqueous solution of ammonium polyacrylate, and the components were mixed together for two hours, thereby preparing a slurry for spraying. Next, this slurry was supplied to a spraying granulator and was sprayed under conditions of a rotation speed of an atomizer of 15,000 rpm, a temperature of 200° C., and a slurry supply amount of 5 ml/min, thereby producing complex particles. Next, the obtained complex particles are fired in a nitrogen atmosphere under a condition of 2,000° C., thereby obtaining agglomerated boron nitride having an average particle diameter of 80 μm.

Here, the average particle diameter of the agglomerated boron nitride was obtained by measuring the volume-based particle size distribution of the particles using a laser diffraction-type particle size distribution measurement instrument (manufactured by Horiba, Ltd., LA-500) and computing the median diameter (D₅₀) thereof.

(Production of Thermal Conductive Sheet)

In Examples 1A to 4A and Comparative Examples 1A to 3A, thermal conductive sheets were produced in the following manner.

First, according to a formulation shown in Table 1, an epoxy resin, a cyanate resin, a curing agent, and, if necessary, a flexibility-imparting agent were added to methyl ethyl ketone which was a solvent and stirred together, thereby obtaining a solution of a resin composition. Next, a thermal conductive filler was added to this solution, and the components were preliminarily mixed together and then kneaded using three rolls, thereby obtaining a resin composition in which the thermal conductive filler was uniformly dispersed. Next, the obtained resin composition was aged under conditions of 60° C., 0.6 MPa, and 15 hours. Therefore, a thermal conductive resin composition (P) was obtained. Next, the thermal conductive resin composition (P) was applied onto a copper foil using a doctor blade method, and then dried by a 30-minute thermal treatment at 100° C., thereby producing a B-stage-form thermal conductive sheet having a film thickness of 400 μm.

Meanwhile, the details of the respective components in Table 1 are as described below.

(Epoxy Resin (A1))

Epoxy resin 1: An epoxy resin having a dicyclopentadiene skeleton (XD-1000, manufactured by Nippon Kayaku Co., Ltd.)

Epoxy resin 2: An epoxy resin having a biphenyl skeleton (YX-4000, manufactured by Mitsubishi Chemical Industries Corporation)

(Cyanate Resin (A2))

Cyanate resin 1: A novolac-type cyanate resin (PT-30, manufactured by Lonza Japan)

(Thermal Conductive Filler (B))

Filler 1: Agglomerated boron nitride produced by the above-described production example

Filler 2: Alumina (manufactured by Nippon Light Metal Company, Ltd., LS-210)

(Flexibility-Imparting Agent (D))

Epoxy resin 3: A bisphenol F-type epoxy resin (830S, manufactured by DIC Corporation)

Epoxy resin 4: A bisphenol A-type epoxy resin (828, manufactured by Mitsubishi Chemical Industries Corporation)

Phenoxy resin 1: A bisphenol A-type phenoxy resin (YP-55U, manufactured by Nippon Steel & Sumikin Chemical Co., Ltd., weight-average molecular weight: 4.2×10⁴)

Phenoxy resin 2: A phenoxy resin having a bisphenol acetophenone skeleton (YX6954, manufactured by Mitsubishi Chemical Industries Corporation, weight-average molecular weight: 6.0×10⁴)

(Curing Catalyst E-1)

Curing catalyst 1: 2-Phenyl-4,5-dihydroxymethylimidazole (2PHZ-PW, manufactured by Shikoku Chemicals Corporation)

Curing catalyst 2: 2-Phenyl-4-methylimidazole (2P4MZ, manufactured by Shikoku Chemicals Corporation)

Curing catalyst 3: Triphenylphosphine (2PHZ-PW, manufactured by Hokko Chemical Industry Co., Ltd.)

(Curing Catalyst E-2)

Phenol-based curing agent 1: Trisphenylmethane-type phenol novolac resin (MEH-7500, manufactured by Meiwa Plastic Industries, Ltd.)

Phenol-based curing agent 2: Phenol aralkyl resin having a biphenylene skeleton (MEH-7851-S, manufactured by Meiwa Plastic Industries, Ltd.)

(Measurement of Glass Transition Temperature (Tg))

The glass transition temperatures of thermal conductive sheet cured substances were measured as described below. First, the thermal conductive resin composition (P) obtained during the production of the above-described thermal conductive sheet was thermally treated at 100° C. for 30 minutes, thereby producing a B-stage-form thermal conductive sheet having a film thickness of 400 μm. Next, the thermal conductive sheet was thermally treated at 180° C. and 10 MPa for 40 minutes, thereby obtaining a thermal conductive sheet cured substance. Next, the glass transition temperature (Tg) of the obtained cured substance was measured by a dynamic mechanical analysis (DMA) under conditions of a temperature-increase rate of 5° C./min and a frequency of 1 Hz.

(Measurement of Storage Elastic Modulus E′)

The storage elastic moduli E′ of thermal conductive sheet cured substances were measured as described below. First, the thermal conductive resin composition (P) obtained during the production of the above-described thermal conductive sheet was thermally treated at 100° C. for 30 minutes, thereby producing a B-stage-form thermal conductive sheet having a film thickness of 400 μm. Next, the thermal conductive sheet was thermally treated at 180° C. and 10 MPa for 40 minutes, thereby obtaining a thermal conductive sheet cured substance. Next, the storage elastic modulus E′ at 50° C. of the obtained cured substance was measured by a dynamic mechanical analysis (DMA). Here, the storage elastic modulus E′ was the value of the storage elastic modulus E′ at 50° C. which was measured from 25° C. to 300° C. at a frequency of 1 Hz and a temperature-increase rate of 5 to 10° C./minute after a tensile load was applied to the thermal conductive sheet cured substance.

(Thermal Conductivity Test)

The thermal conductive resin composition (P) obtained during the production of the above-described thermal conductive sheet was thermally treated at 100° C. for 30 minutes, thereby producing a B-stage-form thermal conductive sheet having a film thickness of 400 μm. Next, the thermal conductive sheet was thermally treated at 180° C. and 10 MPa for 40 minutes, thereby obtaining a thermal conductive sheet cured substance. Next, the thermal conductivity of the thermal conductive sheet cured substance in the thickness direction was measured using a laser flash method.

Specifically, the thermal conductivity was computed from the following expression using a thermal diffusion coefficient (a) measured using a laser flash method (a half time method), a specific heat (Cp) measured using a DSC method, and a density (p) measured according to JIS-K-6911. The unit of the thermal conductivity is W/(m·K). The measurement temperature was 25° C. Thermal conductivity [W/(m·K)]=α [mm²/s]×Cp [J/kg·K]×ρ [g/cm³]. The evaluation standards are as described below.

A: Equal to or more than 10 W/(m·K)

B: Equal to or more than 3 W/(m·K) and less than 10 W/(m·K)

C: Less than 3 W/(m·K)

(Flex Resistance Test)

The thermal conductive resin composition (P) obtained during the production of the above-described thermal conductive sheet was thermally treated at 100° C. for 30 minutes, thereby producing a B-stage-form thermal conductive sheet having a film thickness of 400 μm. Next, a 100 mm×10 mm piece was cutout from the thermal conductive sheet and was folded along the curved surface of a cylinder having a diameter of 10 mm and the curved surface of a cylinder having a diameter of 6 mm at a bending angle of 180 degrees in an environment of 25° C. at the central portion in the longitudinal direction. Thermal conductive sheets in which cleavage was generated on the thermal conductive sheet surface, the long side of the cleavage was equal to or more than 2 mm, and the maximum value of the cleavage width in a direction perpendicular to the long side was equal to or more than 50 μm were determined to crack. The evaluation standards are as described below.

A: Cracks were not generated on both the cylinder having a diameter of 6 mm and the cylinder having a diameter of 10 mm.

B: Cracks were not generated on the cylinder having a diameter of 10 mm.

C: Cracks were generated on the cylinder having a diameter of 10 mm.

(Manufacturing Stability Evaluation)

For each of Examples 1A to 4A and Comparative Examples 1A to 3A, the manufacturing stability of a semiconductor package was evaluated as described below.

First, ten semiconductor packages illustrated in FIG. 1 were produced using the obtained thermal conductive sheet. Here, cases in which cracking or chipping did not occur in the thermal conductive sheets or the thermal conductive materials in the middle of manufacturing the semiconductor packages, and the ten semiconductor packages all could be stably manufactured were evaluated to be “O”, and cases in which cracking or chipping occurred even in one thermal conductive sheet or one thermal conductive material in the middle of manufacturing the semiconductor packages were evaluated to be “X”.

(Insulation Reliability Evaluation)

For the semiconductor packages evaluated to be “O” in the manufacturing stability evaluation, the continuous humid insulation resistance was evaluated under conditions of a temperature of 85° C. a humidity of 85%, and an alternating applied voltage of 1.5 kV. Meanwhile, resistance values of equal to or less than 10⁶ Ω were considered as faults. The evaluation standards are as described below.

A: Faults did not occur for equal to or longer than 300 hours.

B: Faults occurred for equal to or longer than 200 hours and shorter than 300 hours.

C: Faults occurred for equal to or longer than 150 hours and shorter than 200 hours.

D: Faults occurred for equal to or longer than 100 hours and shorter than 150 hours.

E: Faults occurred within shorter than 100 hours.

(Measurement of Volume Resistivity at 175° C.)

The volume resistivity of the thermal conductive sheet cured substances was measured as described below. First, the obtained thermal conductive sheet was thermally treated at 180° C. and 10 MPa for 40 minutes, thereby obtaining a thermal conductive sheet cured substance. Next, the volume resistivity of the obtained cured substance was measured using an ULTRA HIGH RESISTANCE METER R8340A (manufactured by ADC Corporation) according to JIS K6911 one minute after the application of a voltage at an applied voltage of 1,000 V.

Meanwhile, a main electrode was produced using conductive paste. The main electrode was produced to a circular shape having φ of 50 mm. In addition, a guard electrode having an inner diameter φ of 70 mm and an outer diameter φ of 80 mm was produced around the main electrode. Furthermore, a counter electrode having φ of 83 mm was produced. The evaluation standards are as described below.

O: The volume resistance value was equal to or more than 1×10¹⁰ Ω·cm.

Δ: The volume resistance value was equal to or more than 1×10⁹ Ω·cm and less than 1×10¹⁰ Ω·cm.

X: The volume resistance value was less than 1×10⁹ Ω·cm.

TABLE 1

| | | | | Example | Example | Example | Example | Comparative | Comparative | Comparative |
|---|---|---|---|---|---|---|---|---|---|---|
| | | | Unit | 1A | 2A | 3A | 4A | Example 1A | Example 2A | Example 3A |
| Thermal | Epoxy resin | Epoxy resin 1 | % by mass | 5.0 | 5.0 | 2.5 | 5.0 | 17.5 | | |
| conductive | | Epoxy resin 2 | % by mass | | | | | | 12.5 | |
| resin | Cyanate | Cyanate resin 1 | % by mass | 10.0 | 10.0 | 15.0 | 10.0 | | 12.5 | 5.0 |
| composition | resin | | | | | | | | | |
| | Thermal | Filler 1 | % by mass | 74.8 | 74.8 | 74.8 | 74.8 | 74.8 | 74.5 | |
| | conductive | Filler 2 | % by mass | | | | | | | 75.0 |
| | filler | | | | | | | | | |
| | Flexibility- | Epoxy resin 3 | % by mass | 5.0 | | 5.0 | 5.0 | | | 5.0 |
| | imparting | Epoxy resin 4 | % by mass | | 5.0 | | | | | |
| | agent | Phenoxy resin 1 | % by mass | 5.0 | 5.0 | 2.5 | | | | 11.0 |
| | | Phenoxy resin 2 | % by mass | | | | 5.0 | | | |
| | Curing agent | Curing catalyst 1 | % by mass | | | | | 0.2 | | |
| | | Curing catalyst 2 | % by mass | 0.2 | 0.2 | 0.2 | 0.2 | | | 0.2 |
| | | Curing catalyst 3 | % by mass | | | | | | 0.5 | |
| | | Phenol-based | % by mass | | | | | 7.5 | | |
| | | curing agent 1 | | | | | | | | |
| | | Phenol-based | % by mass | | | | | | | 3.8 |
| | | curing agent 2 | | | | | | | | |

| | | | | | | | | |
|---|---|---|---|---|---|---|---|---|
| Glass transition temperature (Tg) | ° C. | 232 | 239 | 261 | 229 | 197 | 288 | 121 |
| Storage elastic modulus E′ | GPa | 25 | 27 | 28 | 28 | 26 | 22 | 22 |
| Thermal conductivity | W/(m · K) | A | A | A | A | A | A | C |
| Flex resistance test | — | B | B | A | B | C | C | A |
| Volume resistivity (175° C.) | Ω · m | ◯ | ◯ | ◯ | ◯ | ◯ | Δ | X |
| Manufacturing stability evaluation | — | ◯ | ◯ | ◯ | ◯ | X | X | ◯ |
| Insulation reliability evaluation | — | A | A | A | A | — | — | E |

The semiconductor packages for which the thermal conductive sheets of Examples 1A to 4A were used were excellent in terms of the insulation reliability. That is, according to the thermal conductive resin compositions (P) of Examples 1A to 4A, it was possible to stably manufacture the semiconductor packages having excellent reliability.

On the other hand, for the thermal conductive sheets of Comparative Examples 1A and 2A, cracking or chipping occurred on the surfaces when the thermal conductive sheets were applied to the semiconductor devices, and it was not possible to stably manufacture the semiconductor devices. In addition, the thermal conductive sheet of Comparative Example 3A was poor in terms of the thermal conduction properties and the volume resistance value at 175° C. The semiconductor packages for which the above-described thermal conductive sheets were used were poor in terms of insulation reliability.

### Examples and Comparative Examples of Second Invention

Hereinafter, the second invention will be described using examples and comparative examples, but the second invention is not limited thereto. Meanwhile, in the examples and the comparative examples, unless particularly described otherwise, ‘parts’ indicates “parts by mass”. In addition, individual thicknesses indicate average film thicknesses.

(Production Example of Thermal Conductive Filler)

A mixture obtained by mixing melamine borate and scale-like boron nitride powder (average long diameter: 15 μm) was added to an aqueous solution of ammonium polyacrylate, and the components were mixed together for two hours, thereby preparing a slurry for spraying. Next, this slurry was supplied to a spraying granulator and was sprayed under conditions of a rotation speed of an atomizer of 15,000 rpm, a temperature of 200° C., and a slurry supply amount of 5 ml/min, thereby producing complex particles. Next, the obtained complex particles are fired in a nitrogen atmosphere under a condition of 2,000° C., thereby obtaining agglomerated boron nitride having an average particle diameter of 80 μm.

Here, the average particle diameter of the agglomerated boron nitride was obtained by measuring the volume-based particle size distribution of the particles using a laser diffraction-type particle size distribution measurement instrument (manufactured by Horiba, Ltd., LA-500) and computing the median diameter (D₅₀) thereof.

(Production of Thermal Conductive Sheet)

In Examples 1B to 3B and Comparative Examples 1B and 2B, thermal conductive sheets were produced in the following manner.

First, according to a formulation shown in Table 2, an epoxy resin, a cyanate resin, a curing agent, and a flexibility-imparting agent were added to methyl ethyl ketone which was a solvent and stirred together, thereby obtaining a solution of a resin composition. Next, a thermal conductive filler and silica nanoparticles were added to this solution, and the components were preliminarily mixed together and then kneaded using three rolls, thereby obtaining a resin composition in which the thermal conductive filler and the silica nanoparticles were uniformly dispersed. Next, the obtained resin composition was aged under conditions of 60° C., 0.6 MPa, and 15 hours. Therefore, a thermal conductive resin composition (P) was obtained. Next, the thermal conductive resin composition (P) was applied onto a copper foil using a doctor blade method, and then dried by a 30-minute thermal treatment at 100° C., thereby producing a B-stage-form thermal conductive sheet having a film thickness of 400 μm.

Meanwhile, the details of the respective components in Table 2 are as described below.

(Epoxy Resin (A1))

Epoxy resin 1: An epoxy resin having a dicyclopentadiene skeleton (XD-1000, manufactured by Nippon Kayaku Co., Ltd.)

(Cyanate Resin (A2))

Cyanate resin 1: A novolac-type cyanate resin (PT-30, manufactured by Lonza Japan)

(Thermal Conductive Filler (B))

Filler 1: Agglomerated boron nitride produced by the above-described production example

Filler 2: Alumina (manufactured by Nippon Light Metal Company, Ltd., LS-210)

(Silica Nanoparticles (C))

Nano silica 1: RX200, manufactured by Nippon Aerosil Co., Ltd., average particle diameter D₅₀: 12 nm

Nano silica 2: RX50, manufactured by Nippon Aerosil Co., Ltd., average particle diameter D₅₀: 50 nm

Nano silica 3: SO-25R, manufactured by Admatechs Co., Ltd., average particle diameter D₅₀: 500 nm

(Flexibility-Imparting Agent (D))

Epoxy resin 3: A bisphenol F-type epoxy resin (830S, manufactured by DIC Corporation)

Phenoxy resin 1: A bisphenol A-type phenoxy resin (YP-55U, manufactured by Nippon Steel & Sumikin Chemical Co., Ltd., weight-average molecular weight: 4.2×10⁴)

(Curing Catalyst E-1)

Curing catalyst 2: 2-Phenyl-4-methylimidazole (2P4MZ, manufactured by Shikoku Chemicals Corporation)

(Measurement of Glass Transition Temperature (Tg), Measurement of Storage Elastic Modulus E′, and Thermal Conductivity Test)

The measurement of the glass transition temperatures (Tg), the measurement of the storage elastic moduli E′, and thermal conductivity test were the same as in the examples and the comparative examples of the first invention, and thus the description thereof will not be repeated.

(Preservation Stability Evaluation)

For each of Examples 1B to 3B and Comparative Examples 1B and 2B, the preservation stability of a varnish-form thermal conductive resin composition (P) obtained during the production of the above-described thermal conductive sheet was evaluated as described below.

The thermal conductive resin composition (P) in which the thermal conductive filler and the silica particles were uniformly dispersed was injected into a cylindrical container having a diameter of 80 mm so as to obtain a height of 100 mm. Next, this container was left to stand in an environment of 25° C. for five hours, then, the liquid height of transparent supernatant liquid appearing on the varnish liquid surface was measured, and the preservation stability of the thermal conductive resin composition (P) was evaluated.

A: There was no supernatant liquid.

B: The height of the supernatant liquid was less than 2 mm.

C: The height of the supernatant liquid was equal to or more than 2 mm.

TABLE 2

| | | | | Example | Example | Example | Comparative | Comparative |
|---|---|---|---|---|---|---|---|---|
| | | | Unit | 1B | 2B | 3B | Example 1B | Example 2B |
| Thermal | Epoxy resin | Epoxy resin 1 | % by mass | 5.0 | 5.0 | 5.0 | 5.0 | 5.0 |
| conductive | Cyanate | Cyanate resin 1 | % by mass | 10.0 | 10.0 | 10.0 | 10.0 | 10.0 |
| resin | resin | | | | | | | |
| composition | Thermal | Filler 1 | % by mass | 74.1 | 73.3 | 73.3 | 73.3 | 74.6 |
| | conductive | Filler 2 | % by mass | | | | | |
| | filler | | | | | | | |
| | Silica | Nanosilica 1 | % by mass | 0.7 | 1.5 | | | 0.2 |
| | nanoparticles | Nanosilica 2 | % by mass | | | 1.5 | | |
| | | Nanosilica 3 | % by mass | | | | 1.5 | |
| | Flexibility- | Epoxy resin 3 | % by mass | 5.0 | 5.0 | 5.0 | 5.0 | 5.0 |
| | imparting | Phenoxy resin 1 | % by mass | 5.0 | 5.0 | 5.0 | 5.0 | 5.0 |
| | agent | | | | | | | |
| | Curing agent | Curing catalyst 2 | % by mass | 0.2 | 0.2 | 0.2 | 0.2 | 0.2 |

| | | | | | | |
|---|---|---|---|---|---|---|
| Glass transition temperature (Tg) | ° C. | 230 | 231 | 230 | 230 | 232 |
| Storage elastic modulus E′ | GPa | 27 | 29 | 27 | 25 | 25 |
| Thermal conductivity | W/(m · K) | A | A | A | A | A |
| Preservation stability evaluation | — | B | A | B | C | C |

The thermal conductive resin compositions (P) of Examples 1B to 3B were excellent in terms of preservation stability. On the other hand, the thermal conductive resin compositions (P) of Comparative Examples 1B to 2B were poor in terms of preservation stability.

This application claims priority on the basis of Japanese Patent Application No. 2015-144170 filed on Jul. 21, 2015, the content of which is fully incorporated herein by reference.

1. A thermal conductive resin composition comprising;
an epoxy resin;
a cyanate resin; and
a thermal conductive filler,
wherein a content of the thermal conductive filler is equal to or more than 60% by mass and equal to or less than 85% by mass with respect to 100% by mass of the total solid content of the thermal conductive resin composition, and
wherein a thermal conductivity at 25° C., which is measured by the following thermal conductivity test, is equal to or more than 3 W/(m·k), and cracking does not occur when the following flex resistance test is carried out.
<Thermal Conductivity Test>
The thermal conductive resin composition is thermally treated at 100° C. for 30 minutes, thereby producing a B-stage-form thermal conductive sheet having a film thickness of 400 then, the thermal conductive sheet is thermally treated at 180° C. and 10 MPa for 40 minutes, thereby obtaining a thermal conductive sheet cured substance, and then the thermal conductivity of the thermal conductive sheet cured substance in a thickness direction is measured using a laser flash method.
<Flex Resistance Test>
The thermal conductive resin composition is thermally treated at 100° C. for 30 minutes, thereby producing a B-stage-form thermal conductive sheet having a film thickness of 400 and then a 100 mm×10 mm piece is cut out from the thermal conductive sheet and is folded along a curved surface of a cylinder having a diameter of 10 mm at a bending angle of 180 degrees in an environment of 25° C. at a central portion in a longitudinal direction.

2. The thermal conductive resin composition according to claim 1,
wherein a glass transition temperature of a cured substance of the thermal conductive resin composition, which is measured by a dynamic mechanical analysis under conditions of a temperature-increase rate of 5° C./min and a frequency of 1 Hz, is equal to or higher than 175° C.

3. The thermal conductive resin composition according to claim 1,
wherein a storage elastic modulus E′ at 50° C. of the cured substance of the thermal conductive resin composition is equal to or more than 10 GPa and equal to or less than 40 GPa.

4. The thermal conductive resin composition according to claim 1, further comprising:
at least one flexibility-imparting agent selected from a phenoxy resin and an epoxy resin in a liquid form at 25° C.

5. The thermal conductive resin composition according to claim 1, further comprising:
silica nanoparticles.

6. The thermal conductive resin composition according to claim 1,
wherein the epoxy resin includes one or more selected from an epoxy resin having a dicyclopentadiene skeleton, an epoxy resin having an adamantane skeleton, an epoxy resin having a phenol aralkyl skeleton, an epoxy resin having a biphenyl aralkyl skeleton, and an epoxy resin having a naphthalene aralkyl skeleton.

7. The thermal conductive resin composition according to claim 1,
wherein the thermal conductive filler includes secondary agglomerated particles constituted of primary particles of scale-like boron nitride.

8. The thermal conductive resin composition according to claim 1,
wherein a content of the cyanate resin is equal to or more than 2% by mass and equal to or less than 25% by mass with respect to 100% by mass of a total solid content of the thermal conductive resin composition.

9. The thermal conductive resin composition according to claim 1,
wherein a volume resistivity at 175° C. of the cured substance of the thermal conductive resin composition, which is measured using the following method, is equal to or more than 1.0×10⁹ Ω·m.
<Method>
The thermal conductive resin composition is thermally treated at 100° C. for 30 minutes, thereby producing a B-stage-form thermal conductive sheet having a film thickness of 400 μm, then, the thermal conductive sheet is thermally treated at 180° C. and 10 MPa for 40 minutes, thereby obtaining a thermal conductive sheet cured substance, and then, the volume resistivity of the obtained cured substance is measured one minute after the application of a voltage at an applied voltage of 1,000 Von the basis of JIS K6911.

10. A thermal conductive resin composition comprising:
an epoxy resin;
a thermal conductive filler; and
silica nanoparticles,
wherein an average particle diameter D₅₀ of the silica nanoparticles, which is measured using a dynamic light scattering method, is equal to or more than 1 nm and equal to or less than 100 nm,
a content of the silica nanoparticles is equal to or more than 0.3% by mass and equal to or less than 2.5% by mass with respect to 100% by mass of a total solid content of the thermal conductive resin composition, and
the thermal conductive filler includes secondary agglomerated particles constituted of primary particles of scale-like boron nitride.

11. The thermal conductive resin composition according to claim 10,
wherein a glass transition temperature of a cured substance of the thermal conductive resin composition, which is measured by a dynamic mechanical analysis under conditions of a temperature-increase rate of 5° C./min and a frequency of 1 Hz, is equal to or higher than 175° C.

12. The thermal conductive resin composition according to claim 10,
wherein a storage elastic modulus E′ at 50° C. of the cured substance of the thermal conductive resin composition is equal to or more than 12 GPa and equal to or less than 50 GPa.

13. The thermal conductive resin composition according to claim 10,
wherein a thermal conductivity at 25° C., which is measured by the following thermal conductivity test, is equal to or more than 3 W/(m·k).
<Thermal Conductivity Test>
The thermal conductive resin composition is thermally treated at 100° C. for 30 minutes, thereby producing a B-stage-form thermal conductive sheet having a film thickness of 400 then, the thermal conductive sheet is thermally treated at 180° C. and 10 MPa for 40 minutes, thereby obtaining a thermal conductive sheet cured substance, and then, the thermal conductivity of the thermal conductive sheet cured substance in a thickness direction is measured using a laser flash method.

14. The thermal conductive resin composition according to claim 10, further comprising:
at least one flexibility-imparting agent selected from a phenoxy resin and an epoxy resin in a liquid form at 25° C.

15. The thermal conductive resin composition according to claim 10,
wherein the epoxy resin includes one or more selected from an epoxy resin having a dicyclopentadiene skeleton, an epoxy resin having an adamantane skeleton, an epoxy resin having a phenol aralkyl skeleton, an epoxy resin having a biphenyl aralkyl skeleton, and an epoxy resin having a naphthalene aralkyl skeleton.

16. A thermal conductive sheet formed by semi-curing the thermal conductive resin composition according to claim 1.

17. A semiconductor device comprising:
a metal plate;
a semiconductor chip provided on a first surface side of the metal plate;
a thermal conductive material joined to a second surface of the metal plate on a side opposite to the first surface; and
an encapsulating resin that encapsulates the semiconductor chip and the metal plate,
wherein the thermal conductive material is formed of the thermal conductive sheet according to claim 16.

18. The thermal conductive resin composition according to claim 1,
wherein the thermal conductive filler includes only boron nitride.

19. The thermal conductive resin composition according to claim 1,
wherein a content of the cyanate resin is larger than a content of the epoxy resin not including epoxy resins in a liquid form at 25° C.

20. The thermal conductive resin composition according to claim 1,
wherein a total content of the cyanate resin and the epoxy resin not including epoxy resins in a liquid form at 25° C. is equal to or more than 5% by mass and equal to or less than 40% by mass with respect to 100% by mass of the total solid content of the thermal conductive resin composition.
